(19) United States
(12) Patent Application Publication
(10) Pub. No.: US 2025/0200350 A1
(43) Pub. Date: Jun. 19, 2025

(54) ELECTRONIC CIRCUIT BASED ON 2T2R RRAM CELLS WITH IMPROVED PRECISION

(71) Applicant: Commissariat à l’énergie atomique et aux énergies alternatives, Paris (FR)

(72) Inventor: Mona EZZADEEN, Grenoble Cedex 9 (FR)

(73) Assignee: Commissariat à l’énergie atomique et aux énergies alternatives, Paris (FR)

(21) Appl. No.: 18/976,454

(22) Filed: Dec. 11, 2024

(30) Foreign Application Priority Data
Dec. 19, 2023 (FR) FR2314511

(51) Int. Cl. G06N 3/063

(52) U.S. Cl. CPC G06N 3/063

(57) ABSTRACT

This electronic circuit implements calculation operations each providing a binary output, and comprises word lines; pairs of complementary bit lines; source lines; a set of memory cells organized according to a matrix including rows and columns, the memory cells of a same row being selectable by a word line, the memory cells of a same column being connected to a pair of complementary bit lines and to a source line; and a reading device implemented during each calculation operation. Each memory cell comprises two memristors and two switches.

The reading device includes:
a logic unit for each column, each being configured to perform a logic operation presenting a switching between a low value and a high value depending solely on the value of the input of the logic unit which is connected to a respective source line during said calculation operation,
a module for converting a number of high or low values at the output of the logic units into an intermediate value dependent on said number of high/low values, the latter being an electrical value the variation of which over time depends on a time constant which is a function of said number of high/low values, and
a comparison module for comparing the intermediate value with a reference value and for outputting a single-bit digital signal dependent on the comparison.

### CROSS-REFERENCE TO RELATED APPLICATIONS

This application is a U.S. non-provisional application claiming the benefit of French Application No. 23 14511, filed on Dec. 19, 2023, which is incorporated herein by reference in its entirety.

### FIELD

The present invention relates to an electronic circuit able to implement calculation operations each providing a binary output.

The invention relates to any type of application using operations applied to binary operands, in particular applications using artificial Binary Neural Networks, also known as BNNs.

### BACKGROUND

A neural network is generally made up of a succession of layers of neurons, each of which takes its inputs from the outputs of the previous layer. More precisely, each layer comprises neurons taking their inputs from the outputs of the neurons in the previous layer. Each layer is linked to the next by a plurality of synapses. A synaptic weight is associated with each synapse. This is a number, such as a binary number, or a distribution, which takes on both positive and negative values. In the case of a dense layer, the input of a neuron is the weighted sum of the outputs of the neurons in the preceding layer, weighting being done by the synaptic weights and followed by activation via an activation function.

It is therefore desirable to develop dedicated hardware architectures, combining memory and calculation, to create fast, low-power neural networks able to learn in real time.

More generally, such dedicated hardware architectures aim to efficiently perform operations applied to binary operands.

A known example is a neural network based on optical technologies.

Another field of research concerns the realization of neurons and neural network synapses based on CMOS (Complementary Metal-Oxide-Semiconductor) technology. The acronym CMOS designates both a manufacturing method and a component obtained by such a manufacturing method.

However, according to each of these technologies, each neuron takes up several tens of micrometers on one side. Moreover, each synapse also occupies several tens of micrometers on one side. As a result, the number of neurons and synapses that can be integrated on a limited surface area, such as that of a microchip, is limited, resulting in reduced neural network performance.

As a result, to reduce the footprint, architectures in which synapses are memristive are specifically studied.

Memristive synapses are synapses using memristors. In electronics, a memristor is a passive electronic component. The name comes from the English words memory and resistor. A memristor is a non-volatile memory component, the value of its electrical resistance changing with the application of a voltage for a certain period of time and remaining at this value in the absence of voltage.

Examples of such an implementation are given in the following documents.

The paper “A compute-in-memory chip based on resistive random-access memory” by W. Wan et al, published in Nature in 2022, describes a conventional technique of encoding binary weights as a resistive state within memory cells (a high resistive state (HRS) to encode 1, and a low resistive state (LRS) to encode 0, for example), and applying input activations to the Bit Line (BL) of each cell. The result, via Ohm's law, is a current in each cell which is proportional to the multiplication between the weights and the inputs, which is summed via Kirchhoff's laws on the common Source Line (SL). The source line current is then proportional to the multiplication-accumulation (MAC) between input activations and their respective weights. This approach is highly sensitive to memory cell variability, which is not negligible for most resistive memories. This variability directly influences the multiplication current within each memory cell, accumulates at the end of the column via Kirchhoff's law, and makes it all the more difficult to read out the result of multiplication-accumulation as the number of activated cells increases. The result is a complex, large-area readout circuit, as well as a limitation on the size of the memory cell matrix due to a maximum number of cells activated in parallel, beyond which reading becomes impossible due to variability. The maximum number of inputs activated in parallel for this technique is typically 256, and then also requires a complex learning circuit and the inclusion of a computer in the learning loop to adapt to the specifics of each chip, making it incompatible with Internet of Things constraints. More generally, the maximum number of inputs activated in parallel is around 9.

The paper “Efficient and Robust Nonvolatile Computing-In-Memory Based on Voltage Division in 2T2R RRAM With Input-Dependent Sensing Control” by L. Wang et al, published in May 2021, describes a technique that is more robust to variability by connecting the weights to the inputs to form a resistive bridge. This approach is based on a ratio of complementary weights, which is more robust to the variability of resistive cells. What is more, in each 2T2R memory cell, the current always flows through a sum of LRS and HRS resistors in series, instead of a single LRS or HRS resistor according to the conventional technique described above. This approach then allows a reduction in current consumption. However, this technique remains sensitive to the variability of resistive cells, also limiting its reliable use to 9 input neurons.

The paper “A crossbar array of magnetoresistive memory devices for in-memory computing” by S. Jung et al, published in Nature in 2022, describes an alternative approach in which the resistive weights are connected in series, rather than in parallel. The weights are stored in 2T2R memory cells, two transistors of which are activated differentially. The multiplication operation between an input and a weight is performed by applying the input to a Word Line (WL) of the 2T2R cell, thus selecting only one of the two resistive elements, the value of which is given by the weight. A voltage is applied to one end of the series of weights, which allows to generate a weighted current corresponding to the multiplication-accumulation between the weights and the inputs. This current charges a capacitor at the bottom of the column. The capacitor voltage is compared with a time reference, allowing the value of the multiplication-accumulation to be digitized over several bits.

Connecting all the weights in series allows the current consumption compared with the two previous approaches to be reduced. However, as the access transistors are also connected in series with the weights, they need to be large enough not to interfere with the calculation. In addition, this approach remains highly sensitive to resistive cell variability, with a maximum neuron size of the order of 64 inputs and can also suffer from delay errors that depend on the activated weight combination.

The paper “Low-Overhead Implementation of Binarized Neural Networks Employing Robust 2T2R Resistive RAM Bridges” by M. Ezzadeen et al, published in September 2021, and EP 4 137 999 A1 describe a final approach aimed at removing the impact of resistive cell variability on the accuracy of the multiplication-accumulation operation. Weights are stored differentially in 2T2R memory cells, and inputs are applied differentially to pairs of complementary Bit Lines BL, BLb. As a result, the weights of the neurons are stored in a memory line, instead of a column. Applying inputs to the complementary Bit Lines BL, BLb creates a resistive bridge by the 2T2R memory cell, the midpoint of which is the source line SL. The source line voltage is amplified and digitized by an inverter, the output of which then corresponds to the multiplication result. The combination of the use of the 2T2R memory cell in a resistive bridge configuration combined with an inverter offers very high robustness for the multiplication calculation. Accumulation is performed using a capacitive bridge connected to the output of the inverters, which is also very robust by design. A comparator is used to compare the accumulation result with the neuron threshold. This approach has been shown to be robust enough to implement neuron sizes of up to 513 inputs, or even more.

The limit of this approach then becomes the precision of the comparator, rather than the variability of the memory cells. Indeed, with a neuron of 513 inputs, the minimum voltage difference across the comparator is of the order of 2 mV, which is a relatively critical threshold for comparator design. Implementing larger neurons would further reduce this voltage difference, making the comparator more prone to error.

### SUMMARY

There is therefore a need for an electronic circuit which, in particular, allows a binary neural network with resistive memory cells to be implemented, and for larger neurons, in other words, with a higher number of inputs.

To this end, the invention has as its object an electronic circuit able to implement calculation operations each providing a binary output, the circuit comprising:
word lines;
pairs of complementary bit lines
source lines;
a set of memory cells organized according to a matrix including rows and columns, the memory cells of a same row being selectable by a word line, the memory cells of a same column being connected to a pair of complementary bit lines and to a source line;
each memory cell comprising two memristors and two switches, each memristor being connected to the same source line and to a respective switch, each memristor storing respectively one weight or the inverse of the same weight by presenting respectively first and second different resistance values; the switches being connected, for their activation, to a respective word line and connected respectively to a pair of complementary bit lines;
   a reading device implemented during each calculation operation, the reading device including:
   a logic unit for each column, each logic unit comprising an input terminal connected to a respective source line for receiving an input value, the logic unit being configured to perform a logic operation presenting a switch between a low value and a high value depending solely on the value of the input of the logic unit which is connected to the source line during said calculation operation,
   a conversion module configured to convert a number of high or low values at the output of the logic units into an intermediate value dependent on said number of high or low values at the output of the logic units, the intermediate value being an electrical value, such as an electrical voltage, the variation of which over time depends on a time constant, and the value of the time constant being a function of the number of high or low values at the output of the logic units, the conversion module including a set of interconnected same elements and a set of switches, each element being associated with the output of a respective logic unit, each switch being connected to the output of a respective logic unit and configured to activate, or respectively inhibit, the corresponding element according to the high or low value at the output of the respective logic unit, and the value of the time constant depending on the number of activated elements, and
   a comparison module configured to compare the intermediate value with a reference value and to output a one-bit digital signal, depending on the comparison and corresponding to the output of the electronic circuit, the output signal being representative of the result of the calculation operation.

The electronic circuit according to the invention then offers the advantage of the last-mentioned approach not presenting a problem of memory cell variability, while at the same time having no accuracy limit, accuracy being independent of neuron size with the electronic circuit according to the invention, as will be explained in more detail later.

According to other advantageous aspects of the invention, the electronic circuit comprises one or more of the following features, taken alone or in any technically possible combination:
the value of the time constant is directly proportional to the number of high or low output values of the logic units;
the value of the time constant is equal to the product of a capacitance and a resistance, one from among the capacitance and the resistance being predefined, and the other from among the capacitance and the resistance depending on the number of high or low values at the output of the logic units;
each element is preferably a resistor or a capacitor;
the set of same elements is placed between a first supply potential and an intermediate node, and the conversion module further includes a complementary element placed between the intermediate node and a second supply potential;
when each element is a capacitor, the complementary element is a resistor;
when each element is a resistor, the complementary element is a capacitor;
the comparison module is configured to transform the intermediate value into a square-wave signal with a change-of-state edge at a characteristic time instant, the characteristic time instant then being compared with a reference time instant associated with the reference value, and the signal representing the result of the calculation operation then depending on said comparison
the intermediate value is transformed into the square-wave signal via a comparator;
the comparison module includes the comparator and a comparison voltage generator, and the comparator is able to compare the generated voltage with the comparison voltage from the comparison voltage generator;
the characteristic time instant is compared with the reference time instant via a flip-flop switch or via a comparator with a clock reference;
the reference time instant is obtained via a set of the same second elements connected together and a set of second switches, the second elements being the same as those of the conversion module assembly, each second element being associated with the output of a respective logic unit, each second switch being connected to the output of a respective logic unit and configured to activate, or respectively inhibit, the corresponding second element according to the high or low value at the output of the respective logic unit, and each second switch being controlled in an inverted manner relative to the conversion module switch which is connected to the output of the same respective logic unit;
each second element being preferably a resistor or a capacitor;
   each logic unit performs an inverter type logic function during the calculation operation;
   the logic operation performed by the logic unit is an inversion, and the calculation operation is a neural calculation operation, such as the MAC operation;
   the electronic circuit is a neuromorphic circuit able to implement a neural network with binary output, each memory cell being associated with a respective synaptic weight of a neuron, and each pair of complementary bit lines being able to receive complementary input voltages during a neural calculation operation;
   the electronic circuit comprises a first controller allowing to select the memory cells of a row which are connected to the same word line, and comprising a second controller connected to the pairs of bit lines and allowing to apply to each pair of bit lines different and symmetrical voltages relative to a midpoint voltage, the voltage applied to one bit line being greater than or less than that applied to the associated complementary bit line;
   the electronic circuit comprises several distinct sets of memory cells able to function in parallel with the same set of pairs of complementary bit lines and distinct sets of word lines, each set of memory cells being connected to a respective set of word lines;
   the electronic circuit comprises several distinct sets of memory cells able to operate in parallel with a same set of word lines and distinct sets of complementary pairs of bit lines, each set of memory cells being connected to a respective set of pairs of complementary bit lines;
the reading devices of two successive sets of memory cells being preferably connected to each other via a switch,
the switch preferably being further controlled to the closed position during a neural calculation operation to perform said operation with the set of complementary input voltages received by the two sets of memory cells.

### BRIEF DESCRIPTION OF THE DRAWINGS

These features and advantages of the invention will become clearer on reading the following description, given solely by way of nonlimiting example, and made with reference to the appended drawings, in which:

FIG. 1 is a schematic representation of an electronic circuit, according to the invention, able to implement calculation operations each supplying a binary output, the circuit comprising word lines, pairs of complementary bit lines, source lines, a set of memory cells organized according to a matrix including rows and columns, each memory cell including two memristors and two switches, and a reading device implemented during each calculation operation;

FIG. 2 is a schematic representation of one example of a memory cell in the electronic circuit of FIG. 1;

FIG. 3 is a graph showing the effect of varying memristor state resistance values;

FIG. 4 is a schematic representation of one example of a component performing an XNOR operation and forming part of the reading device of the electronic circuit of FIG. 1;

FIG. 5 illustrates the four possible cases of operation of the XNOR component of FIG. 4;

FIG. 6 is a schematic representation of the output voltage of the XNOR component of FIG. 4 in certain cases of FIG. 5;

FIG. 7 is a more functional schematic representation of the electronic circuit of FIG. 1, and in particular of the reading device;

FIG. 8 is a schematic representation of the reading device of FIG. 1 according to a first embodiment;

FIG. 9 is a chronogram of the discharge of a conversion bridge and the generation of a conversion signal, in the case of the unbiased electronic circuit of FIG. 8;

FIG. 10 is a chronogram similar to that of FIG. 9, in the case of the biased electronic circuit of FIG. 8;

FIG. 11 is a schematic representation similar to that of FIG. 8, according to second and third embodiments;

FIG. 12 is a schematic representation similar to that of FIG. 8 according to a fourth embodiment;

FIG. 13 is a schematic representation similar to that of FIG. 8 according to a fifth embodiment;

FIG. 14 is a schematic representation similar to that of FIG. 8 according to sixth and seventh embodiments;

FIG. 15 is a schematic representation similar to that of FIG. 8 according to an eighth embodiment;

FIG. 16 is a schematic representation of an electronic circuit according to the invention comprising several distinct sets of memory cells connected in series to one another and to the same set of word lines, these sets of memory cells being able to operate in parallel by being controlled by distinct sets of pairs of complementary bit lines;

FIG. 17 is a schematic representation of an electronic circuit according to the invention comprising a matrix of distinct sets of memory cells, the sets of memory cells being connected to each other in the form of rows and columns, the sets in the same row being connected to the same set of word lines, and the sets in the same column being connected to the same set of pairs of complementary bit lines; and

FIG. 18 is a view similar to FIG. 17 according to another embodiment.

### DETAILED DESCRIPTION

Note that the expression “able to” followed by a verb is considered equivalent to the expression “configured for” followed by the same verb. If necessary, the expression “able to” can be replaced by “configured for”, without altering the content of the present invention.

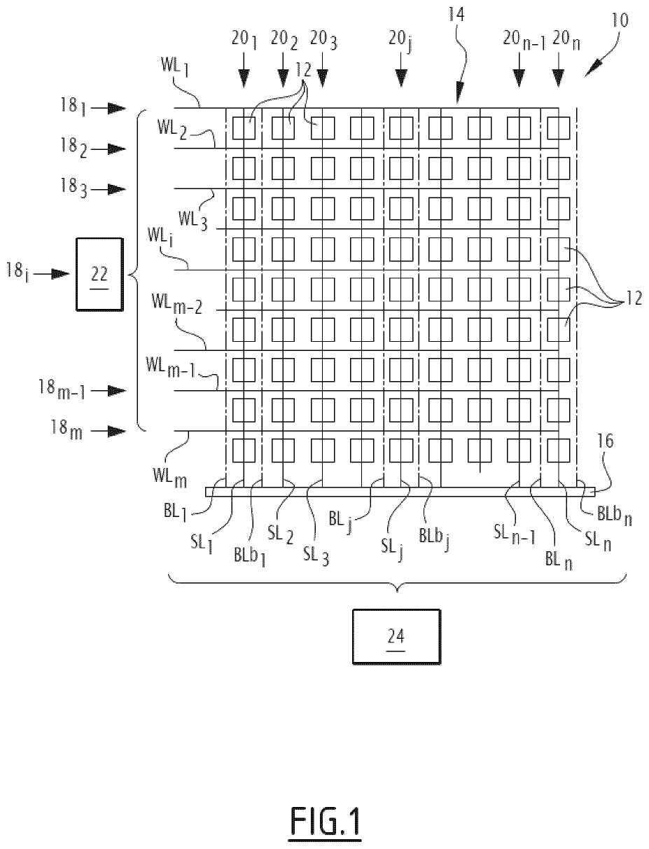

In FIG. 1, an electronic circuit 10 is able to take as input a vector “x” comprising “n” inputs xⱼ and to implement calculation operations each supplying a binary output. The calculation operations performed by the electronic circuit 10 are, for example, neural calculation operations, such as popcount operations (counting the number of 1s in a series of bits), or even MAC operations (Multiply And Accumulate), well known for neural network inference.

The electronic circuit 10 is a neuromorphic circuit able to implement a neural network with binary output, in other words, a network for which synaptic weights and neurons are binary.

The electronic circuit 10 comprises a set of memory cells 12 organized according to a two-dimensional matrix 14, configured to store the values of the synaptic weights of each neuron, and a reading device 16 implemented during each calculation operation.

In FIG. 1, the matrix 14 comprises “m” rows 18 and “n” columns 20, where “m” is the number of rows 18 of matrix 14, and similarly “n” is the number of columns 20 of the matrix 14, “m” and “n” each being an integer greater than or equal to 1.

A memory cell 12 has the coordinates (i,j) when said memory cell 12 is positioned at the intersection of the “i” row 18i and the “j” column 20j with “i” and “j” two integers. The index “i” is then between 1 and “m”, and the index “j” is between 1 and “n”.

The memory cells 12 of the “i” row 18 store the synaptic weights of a neuron. The number of rows 18 is therefore a function of the number of neurons in the neural network implemented by the electronic circuit 10.

The electronic circuit 10 also comprises word lines WL, pairs of complementary bit lines BL and BLb, source lines SL and two controllers 22 and 24.

In the above notations, a word line is referred to as WL (Word Line), complementary bit lines BL and BLb are referred to as BL (Bit Line) and source lines are referred to as SL (Source Line).

In the example of FIG. 1, each memory cell 12 is connected to a respective word line WL, a respective source line SL and a respective pair of complementary bit lines EL and BLb.

Each memory cell 12 in the same row 18 shares the same word line WL, so that the word lines WL can also be indexed with index “i”. Thus, the first word line, in other words, the one connecting the memory cells 12 in the first row 18, can be referenced WL₁.

The memory cells 12 in the same column 20 share the same pair of complementary bit lines BL and BLb and the same source line SL. These three lines can therefore also be indexed with the index “j”.

For the sake of clarity, the set of source lines SL are represented, but only the pairs of complementary bit lines BL and BLb in the first column 20₁, the “j” column 20ⱼ and the last column 20ₙ are represented as mixed lines in FIG. 1.

The memory cells 12 in the same row 18 are then selectable by a word line WL, and the memory cells 12 in the same column 20 are connected to a pair of complementary bit lines BL, BLb and a source line SL.

The first controller 22 allows to select the memory cells 12 in a row 18 that are connected to the same word line WL, and therefore select a single neuron from among the electronic circuit 10.

The second controller 24 is able to control the pairs of complementary bit lines BL and BLb and the source lines SL.

The second controller 24 is connected to the pairs of bit lines BL, BLb and allows different voltages to be applied to each pair of bit lines BL, BLb, the voltages applied during the calculation operation being advantageously symmetrical relative to a midpoint voltage, the voltage applied to a bit line BL being greater than or less than that applied to the associated complementary bit line BLb.

The first controller 22 and the second controller 24 are configured to be controlled in a coordinated manner to control the memory cells 12 using the lines they control according to the desired operation.

Each memory cell 12 is able to store at least one binary value, such as a binary weight W, in particular a respective binary synaptic weight of the neural network when the calculation operation performed is a neural computation operation.

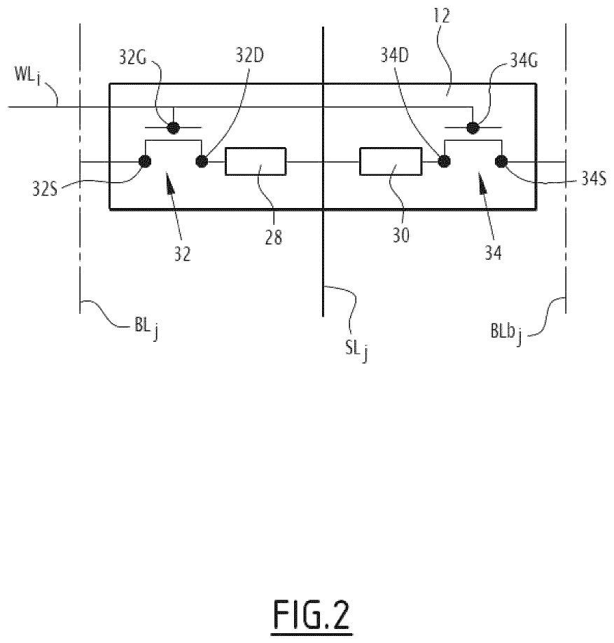

An example of the structure of a memory cell 12 is represented, more precisely in FIG. 2 for the case of a memory cell 12 with coordinates (i,j).

Each memory cell 12 includes two memristors, namely a first memristor 28 and a second memristor 30, as well as two switches, a first switch 32 and a second switch 34.

Because memristors 28 and 30 are present, such a memory cell 12 is a resistive random access memory cell. The memory cell 12 is more often referred to by the acronym RRAM or ReRAM (Resistive random-access memory).

In addition, such an arrangement is generally referred to as a 2T2R structure, in reference to the presence of the two transistors (2T designation) and two memristors (2R designation). The memory cell 12 is sometimes referred to as a 2T2R cell.

A memristor is a component the electrical resistance of which changes permanently when a current is applied. Thus, data can be recorded and rewritten by a control current. Such behavior is observed notably in phase-change materials, ferroelectric tunnel junctions or redox memories based on oxides such as HfOₓ or TiO₂₋ₓ.

The change in conductance of a memristor depends on the amplitude and duration of the voltage pulses applied across the memristor, as well as on the maximum value of current that can flow through the memristor, for example for a “SET” operation, in other words, switching from a high resistance to a low resistance.

A memristor can thus present two states, a high state and a low state.

The high state corresponds to a high resistance and is generally referred to by the abbreviation HRS, which stands for “High Resistive State”. The high state is therefore referred to in the following as the HRS high state.

The low state corresponds to a low resistance and is generally referred to as LRS, which stands for Low Resistive State. The low state is therefore referred to as LRS low state in the following.

However, due to the variability of memristors in operation, the resistance in the HRS high state can be less than the resistance in the LRS low state, generating errors if the information (weight) is encoded in a single memristor.

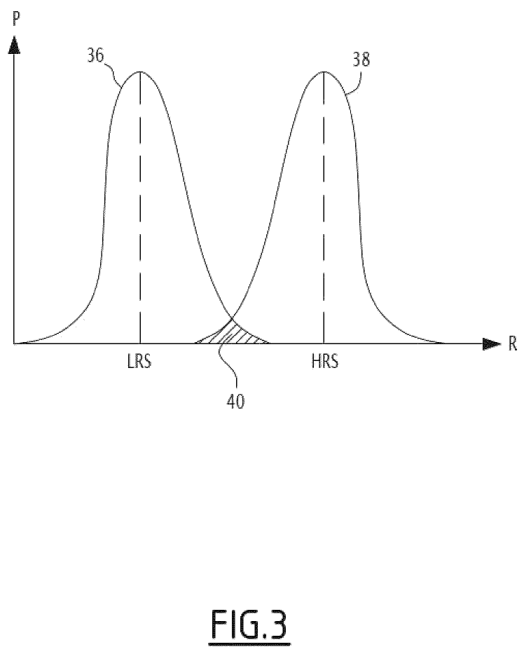

This variability is presented schematically in FIG. 3. In this figure, the probability of a memristor presenting the resistance value in practice is represented as a function of the memristor state.

More precisely, the first curve, noted 36, schematically represents the probability for all values observed in practice for the LRS low state, while the second curve, 38, represents the same curve for the HRS high state.

The graph in FIG. 3 clearly shows that there is an overlap zone 40. In this overlap zone 40, it may be impossible to distinguish between the LRS low and HRS high states.

This overlap can become more pronounced with long term time drifts of the memristors.

To remedy this problem, in the present example, the information is encoded by the ratio between the two resistances of the two states, thanks to a differential configuration of the two memristors 28 and 30.

Also, according to the example described, the memristors 28 and 30 are complementary series memristors respecting the same logic coding.

By complementary, it is understood that the memristors 28 and 30 present a different state, a LRS low state for one and a HRS high state for the other.

According to the example of FIG. 2, a heavy weight, in other words, a logic “1”, is represented by a HRS high state of the first memristor 28 (respectively a LRS low state of the second memristor 30), while a light weight, in other words, a logic “0”, is represented by a LRS low state of the first memristor 28 (respectively a HRS high state of the second memristor 30).

In the example described, each of the two memristors 28 and 30 is connected to the common source line SL.

Each of the two switches 32 and 34 is, for example, a transistor, and more specifically a field-effect transistor.

A field-effect transistor is often referred to by the abbreviation FET.

According to the example described, the two switches 32 and 34 are insulated-gate field-effect transistors. Such a transistor is more commonly known by the acronym MOSFET (Metal Oxide Semiconductor Field Effect Transistor).

Thus, each switch 32 and 34 presents three electrodes, a gate G, a source S and a drain D.

Generally speaking, for a transistor whose reference sign is X, the electrodes will be noted on the figures according to the following notation: gate XG, source XS and drain XD.

This notation is chosen here to simplify the representation, bearing in mind that the positions of the source XS and the drain XD are defined in relation to the main polarization direction, in other words, the one most commonly used for the assembly. Of course, if polarization is inversed, the skilled person will know that the roles and positions of the source XS and the drain XD are exchanged.

Each gate 32G and 34G of the two switches 32 and 34 is connected to the word line WL. According to the voltage level present on the word line, the switches 32 and 34 are made conductive or non-conductive. In practice, the first controller 22 will choose to select a row 18 of cells 12 by a word line WL by making the switches 32, 34 of the memory cells 12 in this row conductive.

The source 32S of the first switch 32 is connected to the bit line BL, while the source 34S of the second switch 34 is connected to the complementary bit line BLb.

The drain 32D of the first switch 32 is connected to one terminal of the first memristor 28, the other terminal of the first memristor 28 being connected to the common source line SL.

The drain 34D of the second switch 34 is connected to one terminal of the second memristor 30, the other terminal of the second memristor 30 being connected to the common source line SL.

The second controller 24 will pilot the power supply to the pairs of bit lines, so that the voltage presented on a bit line BLⱼ is different from and complementary to the voltage presented on the complementary bit line BLbⱼ. Thus, when a cell 12 of coordinates i,j is selected (its switches being made conducting by the activation voltage presented on the associated word line WLᵢ), the memristors 28 and 30 of this cell are in series and constitute a resistive bridge between the bit lines BLⱼ and BLbⱼ.

In this case, the memristors 28 and 30 are thus supplied by voltages present on the bit lines BLⱼ and BLbⱼ that are symmetrical relative to a voltage, for example

$$\frac{{V}_{DD}}{2} ,$$

known as the midpoint voltage. In this notation, V_{DD} corresponds to a supply potential V_{DD}. Furthermore, the ground is referred to as GND in the following. Of course, another midpoint voltage could be chosen, for example, a voltage of

$$\frac{{V}_{DD}}{3} .$$

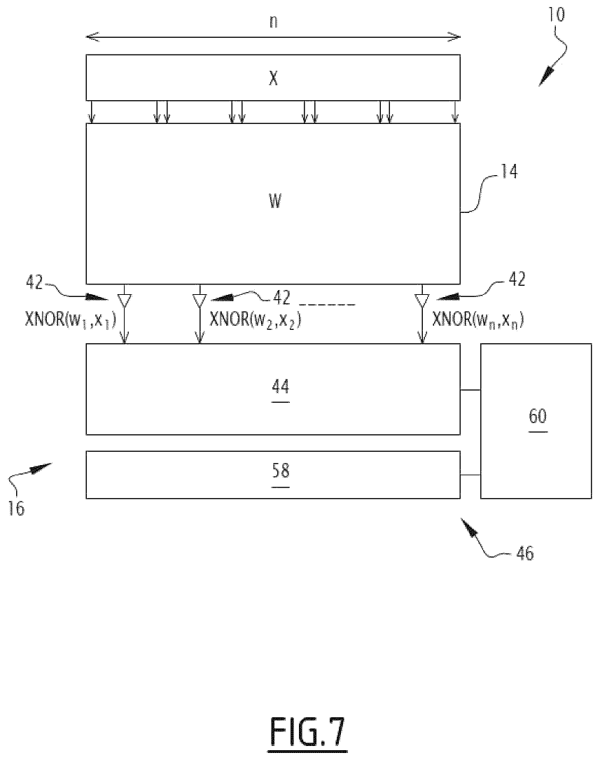

The reading device 16 implemented during each calculation operation will now be described with reference to FIG. 7.

For the sake of clarity, it should be noted that a binary neural network presents a specific inference capability relative to a conventional neural network.

When a classical neural network is applied to an input vector to calculate an output vector, each neuron receives input values corresponding to output values from neurons in a previous layer xⱼ and performs a weighted sum Σⱼ Wᵢⱼ.xⱼ and the neuron then applies a non-linear function “f” to the result of the weighted sum.

In contrast, in a binary neural network, the weighted sum is obtained by performing the following operation:

$${a}_{i} = sign [ {popcount}_{j} XNOR ( {W}_{i j} , {x}_{j} ) - T {h}_{i} ]$$

where aᵢ and xⱼ represent the output values calculated by the neurons of the current layer, respectively by the previous layer;
Wᵢⱼ represents the respective binary weights for the neurons of the current layer;
XNOR is the logic function giving the complement of the exclusive OR function (this function is sometimes referred to as exclusive NOR);
popcount is the function that counts the number of 1s in a series of bits;
Thᵢ is a predefined threshold, and
sign is a function associating the value 1 with a positive input and associating −1 with a negative value.

This means that, in the case of a binary network, it is possible to implement a binary neural calculation via the electronic circuit 10 comprising the reading device 16 as represented in FIG. 7.

The reading device 16 comprises a logic unit 42 for each column 20, a conversion module 44 and a comparison module 46.

Each logic unit 42 forms, in combination with a memory cell 12 selected in the column 20 associated with said logic unit 42, an equivalent component XNOR 43.

The logic unit 42 comprises an input terminal connected to the source line SL of said memory cell 12 to receive an input value.

Each logic unit 42 is configured to perform a logic operation presenting a switch between a low value and a high value depending solely on the value of the input of the logic unit which is connected to the source line SL during said calculation operation.

More particularly, a logic “1” is represented by a high value at the output of the logic unit 42 and a logic “0” is represented by a low value at the output of the logic unit 42.

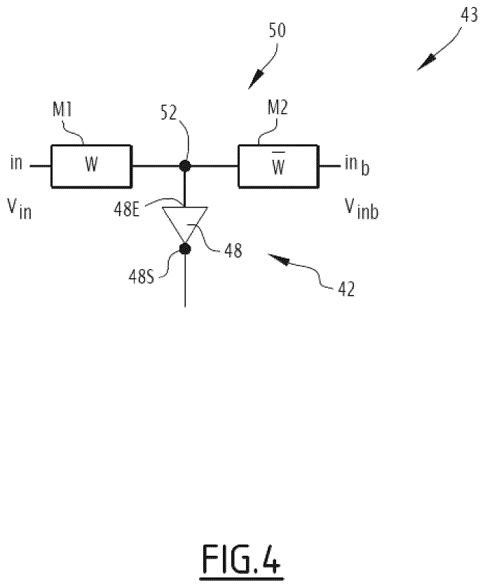

The component XNOR 43 equivalent to the association between the selected memory cell 12 and the logic unit 42 is described now with reference to FIG. 4.

The component XNOR 43 performs an XNOR operation on two signals, namely a weight noted W, and an input signal noted “in”.

In this case, the component XNOR 43 includes two memristors M1 and M2 and a logic unit 42.

In the example of FIG. 4, the logic unit 42 is an inverter 48.

The two memristors M1 and M2 are complementary memristors connected in series corresponding to the weight W.

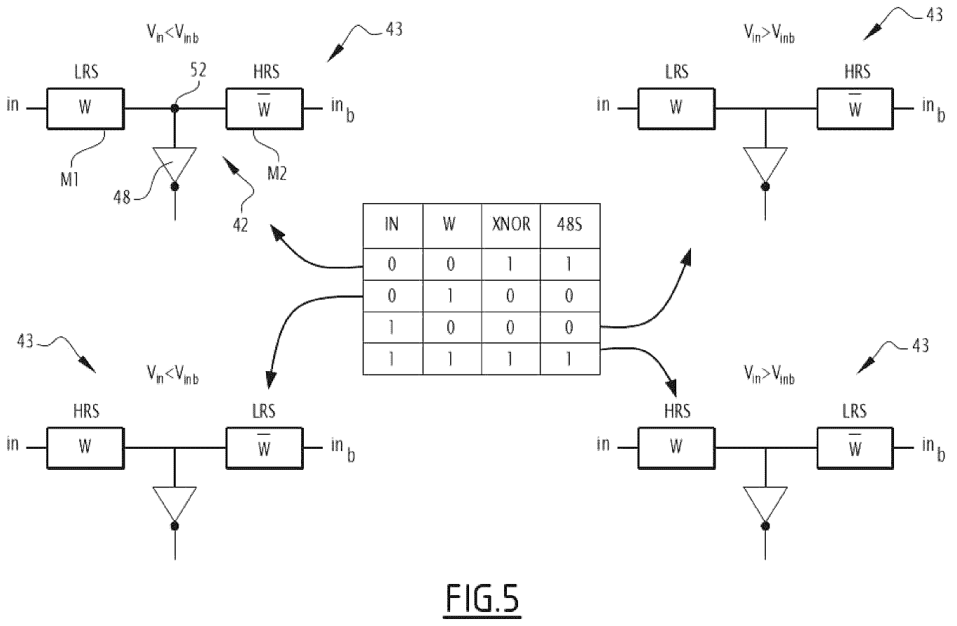

Also, similar to what has been described previously, according to the example in FIG. 5, a logic “1” for the weight W is represented by a HRS high state of the memristor M1 (the other memristor M2 being in the LRS low state) while a logic “0” for the weight W is represented by a LRS low state of the memristor M1 (the other memristor M2 being in the HRS high state).

The memristors M1 and M2 are connected at one end to the inverter 48 and at the other end to a respective voltage.

Note a first voltage Vᵢₙ and a second voltage V_{inb}.

The electrical configuration is therefore that of a voltage divider bridge 50 connected on the one hand to the first voltage Vᵢₙ and on the other to the second voltage V_{inb}, and the midpoint 52 of which is connected to the input of the inverter 48. In other words, one of the memristors M1 is subjected to a voltage |Vᵢₙ−V_{mid}| and the other memristor M2 is subjected to a voltage |V_{mid}−V_{inb}|. The notation V_{mid} refers to the voltage at the midpoint 52 of the divider bridge 50.

Thus, in the case described, the input signal “in” corresponds to the pair of the first voltage Vᵢₙ and the second voltage V_{inb}.

These voltages Vᵢₙ and V_{inb} have, for example, the particularity of being symmetrical relative to half the supply potential

$$\frac{{V}_{DD}}{2} .$$

In practice, it is advantageous to have Vᵢₙ equal to V_{DD} or GND, and V_{inb} equal to GND or V_{DD} respectively.

In the example of FIG. 5, the input signal “in” codes for a logic “1” when the first voltage Vᵢₙ is strictly greater than the second voltage V_{inb}, in other words, Vᵢₙ>V_{inb}. Conversely, the input signal “in” codes for a logic “0” when the first voltage Vᵢₙ is strictly less than the second voltage V_{inb}, in other words, Vᵢₙ<V_{inb}.

This schematic representation of the two memristors M1, M2 in series between two voltages Vᵢₙ and V_{inb} corresponds in practice to the equivalent circuit formed by a selected cell 12 (the associated word line WL presents a voltage making its switches closed) and receiving via the bit lines BL and BLb bias voltages corresponding to Vᵢₙ and V_{inb}. In other words, the input signal “in” is fed to a selected cell 12 via the associated bit lines BL and BLb by the action of the second controller 24. The midpoint 52 of the divider bridge then corresponds to the source line SL connected to the cell 12 in question.

The inverter 48 is an element able to receive a signal incident on an input 48E and perform a logic inversion calculation to emit on an output 48S an output signal which is the inverse of the incident signal.

Here, the input 48E of the inverter 48 is connected to the midpoint 52 of the divider bridge 50 formed by the two memristors M1 and M2.

The output 48S of the inverter 48 gives the result of the operation XNOR applied to the input signal “in” and the weight W.

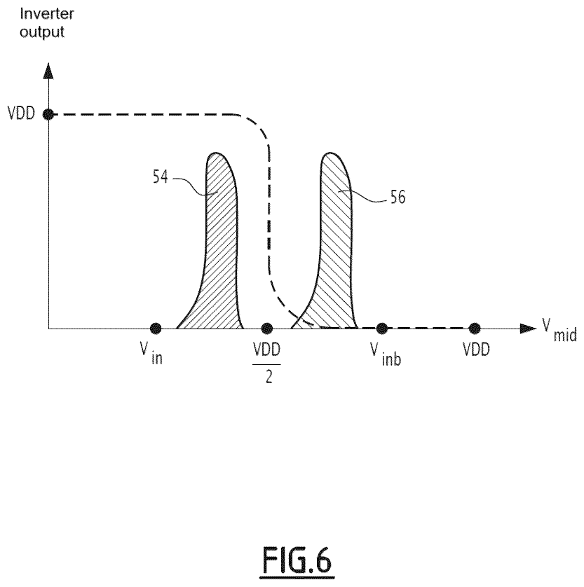

The operation of the equivalent component XNOR 43 is now described with reference to FIGS. 5 and 6, which schematically represent respectively the four possible cases of operation of the component XNOR 43 and the value of the output voltages for two of the four possible cases. In FIG. 5, the reference signs have not been repeated, so as not to make the figures too cumbersome.

Specifically, the top-left case in FIG. 5 corresponds to the case where the input signal “in” is 0 and the value of the weight W is 0.

In such a case, as explained above, the first voltage Vᵢₙ is strictly less than the second voltage V_{inb}, in other words Vᵢₙ<V_{inb} (with, for example, Vᵢₙ=GND and V_{inb}=V_{DD}).

In addition, the first memristor M1 is in the LRS low state, while the second memristor M2 is in the HRS high state.

As a result of the configuration, the memristor in the HRS high state absorbs almost all the voltage dynamic, pushing the voltage V_{mid} from the midpoint 52 toward the voltage at the end of the memristor in the LRS low state.

In this case, this means that the voltage V_{mid} at the midpoint 52 is pushed toward the first voltage Vᵢₙ, as represented schematically by the curve 54 in FIG. 6.

As shown in FIG. 6, the midpoint voltage V_{mid} is clearly below half of the supply potential V_{DD}/2.

The output 48S of the inverter 48 is then at 1.

This shows that for a signal “in” of 0 and a weight of 0, the output of the inverter 48 is 1, which corresponds to XNOR(0,0)=1.

Thus, the output of the logic unit 42 is a logic “1”, so the output of the logic unit 42 is a high value.

The case at the bottom left in FIG. 5 corresponds to the corresponding case in which the input signal “in” is 0 and the value of the weight W is 1.

In such a case, compared with the previous case, the only difference is that the first memristor M1 is in the HRS high state, while the second memristor M2 is in the LRS low state.

As a result, the midpoint voltage V_{mid} is pushed toward the second voltage V_{inb}, as represented schematically by the curve 56 in FIG. 6.

The output 48S of the inverter 48 is then at 0.

This shows that for a signal “in” at 0 and a weight W at 1, the output of the inverter 48 is then at 0, which corresponds to XNOR(0,1)=0.

Thus, the output of the logic unit 42 is a logic “0”, so the output of the logic unit 42 is a low value.

The same remarks apply to the cases on the right in FIG. 5.

The upper case corresponds to an input signal “in” with a value 1 (Vᵢₙ>V_{inb}, with, for example, Vᵢₙ=V_{DD} and V_{inb}=GND) and a weight W with a value 0 (the first memristor M1 in the LRS low state and the second memristor M2 in the HRS high state), so that the midpoint voltage V_{mid} is pushed toward the first voltage Vᵢₙ, in other words

$${V}_{mid} > \frac{{V}_{DD}}{2} .$$

As a result, the output 48S of the inverter 48, and therefore of the logic unit 42, is a logic “0”. This corresponds to the operation XNOR(1,0)=0.

The lower case corresponds to an input signal “in” with a value 1 (Vᵢₙ>V_{inb}) and a weight with a value 1 (the first memristor M1 in the HRS high state and second memristor M2 in the LRS low state), so that the midpoint voltage V_{mid} is pushed toward the second voltage V_{inb}, in other words

$${V}_{m i d} < \frac{{V}_{D D}}{2} .$$

As a result, the output 48S of the inverter 48, and therefore of the logic unit, is a logic “1”. This corresponds to the operation XNOR(1,1)=1.

The various cases described lead to the truth table seen in FIG. 5 being obtained, which clearly illustrates that the inverter output 48S performs an XNOR operation.

Such a component XNOR 43 allows a voltage output to be obtained which does not present the resistance variability of the memristors M1 and M2.

The reduction in variability comes from two complementary factors.

A first reduction in variability is obtained by using the differential connection of the two memristors M1 and M2. However, at the midpoint 52 of the divider bridge 50, the signal is still subject to the variability of the memristors M1 and M2. In fact, the midpoint voltage depends on the ratio between the resistance values of the memristors M1 and M2, which reduces variability, but not completely.

The second reduction in variability is obtained by using the logic unit 42, as referred to in FIG. 6.

As a result, the output signal of the logic unit 42 is much less sensitive to variations in the resistance of the memristors M1, M2. Only in the worst cases, where the statistical distributions of the resistance values overlap, will there be any residual errors. In practice, however, this overlap can be avoided by applying sufficient programming voltages and currents.

The conversion module 44 is configured to convert a number of high or low values at the output of the logic units 42 into an intermediate value depending on the said number of high or low values at the output of the logic units 42.

As a reminder, a high value corresponds to a logic “1” and a low value corresponds to a logic “0”.

By “intermediate” in “intermediate value”, we mean intermediate in the succession of actions required to perform the calculation operation, from the reception of each input value at the bottom of the column to the emission of the signal representing the result of the calculation operation.

In other words, the intermediate value is representative of the number of logic “1” and “0” in output by the logic units 42 of each column 20.

In particular, the intermediate value is representative of the result of the operation popcount XNOR(Wⱼ,xⱼ).

The intermediate value is, for example, an electrical value, such as an electrical voltage, the variation of which over time depends on a time constant, and the value of the time constant is a function of the number of high or low values at the output of the logic units 42.

The time constant is then directly proportional to the number of high or low values at the output of the logic units 42. For example, the time constant is proportional to the result of the operation popcount XNOR(Wⱼ,xⱼ).

Preferably, the value of the time constant is equal to the product of a capacitance and a resistance, and is then noted RC, one from among the capacitance and the resistance being predefined, and the other of the capacitance and the resistance depending on the number of high or low values at the output of the logic units 42.

The comparison module 46 is configured to compare the intermediate value with a reference value and to output a one-bit digital signal, depending on the comparison and corresponding to the output of the electronic circuit 10, the output signal emitted being representative of the result of the calculation operation.

With reference to FIG. 7, the comparison module 46 comprises an acquisition unit 58 for obtaining the reference value and a comparison unit 60.

The acquisition unit 58 is configured supply as output a reference value comparable to the intermediate value.

For example, if the intermediate value is an electrical voltage, the acquisition unit 58 is configured to supply as output an electrical voltage.

The comparison unit 60 is connected to the conversion module 44 and to the acquisition unit 58.

The comparison unit 60 takes as input the reference value supplied by the acquisition unit 58 and the intermediate value supplied by the conversion module 44 and emits as output a one-bit signal corresponding to the result of the comparison of the intermediate value and the reference value.

The output signal represents a logic “1” or a logic “0”, depending on the comparison between the two preceding values and therefore on the result of the operation.

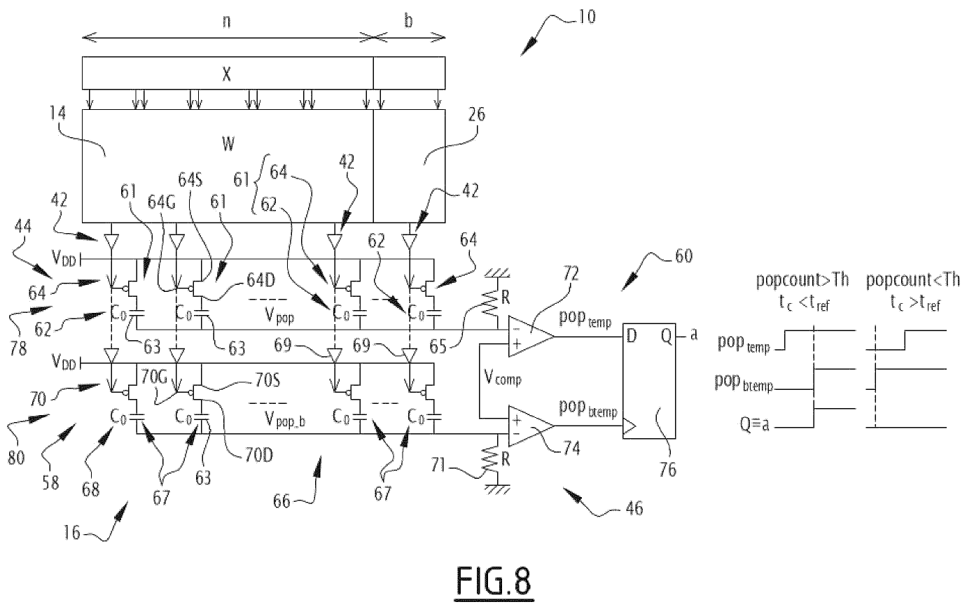

A first embodiment of the reading device 16 of the electronic circuit 10 according to the invention will now be described with reference to FIGS. 8 to 10.

The electronic circuit 10 comprises the matrix 14 of memory cells 12 with “m” rows 18 and “n” columns 20.

As an optional addition, the electronic circuit 10 comprises a further matrix 26 of the cells 12, also referred to as a bias matrix 26, described in more detail later.

The conversion module 44 comprises a set of the same interconnected first elements 62 and a set of first switches 64, each first element 62 being associated with the output of a respective logic unit 42, as represented in FIG. 8.

The number of first elements 62 and the number of first switches 64 are equal, each being equal to the number “n” of columns 20, and therefore to the number of logic units 42.

Each first switch 64 is connected to the output of a respective logic unit 42 and is configured to activate, or respectively inhibit, the corresponding first element 62 according to the value, high or low, at the output of the respective logic unit 42. The value of the time constant then depends on the number of activated first elements 62.

In the example of FIG. 8, if a logic “0” is calculated at the output of a respective logic unit 42, the respective first switch 64 is configured to activate the corresponding first element 62; and by extension if a logic “1” is calculated at the output of a respective logic unit 42, the respective first switch 64 is configured to inhibit the corresponding first element 62. This example of control logic for the first element 62 corresponds to the case where each first switch 64 includes a PMOS transistor. The skilled person will of course understand that the aforementioned control logic is inversed if each first switch 64 includes an NMOS transistor, the respective first switch 64 then being configured to activate the corresponding first element 62 if a logic “1” is calculated at the output of a logic unit 42, and by extension to inhibit the corresponding first element 62 if a logic “0” is calculated at the output of the logic unit 42. The number of activated first element(s) 62 is then equal to n−popcount XNOR(Wⱼ,xⱼ).

The first element 62 and the corresponding first switch 64 form a conversion unit 61 connected to the output of the logic unit 42.

In the example of FIG. 8, each first element 62 comprises a capacitor 63, each first element 62 preferably being constituted of the capacitor 63. Advantageously, the capacitors 63 all have the same capacitance value C₀.

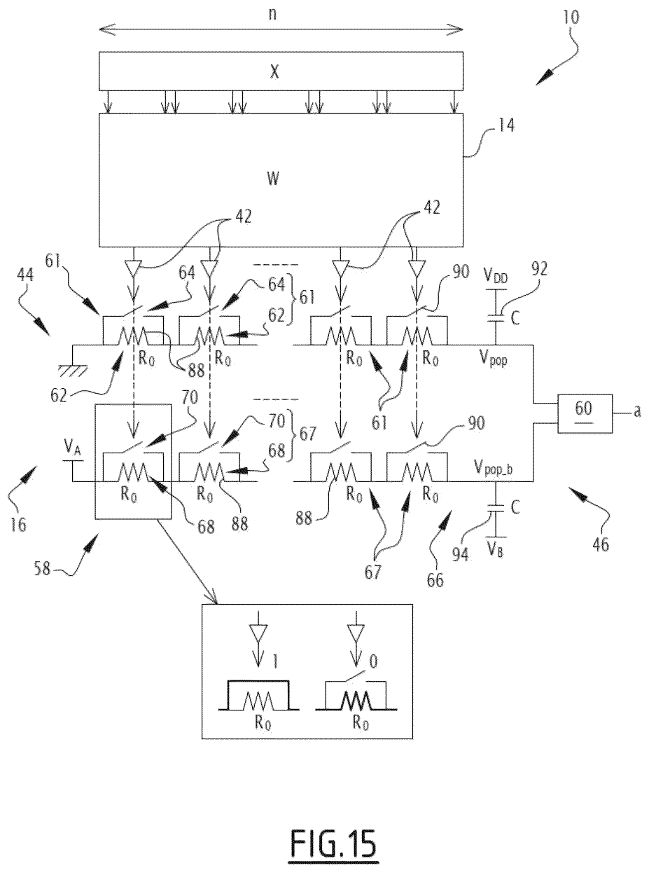

Alternatively, as will be described in more detail in the example of FIG. 15, each first element 62 comprises a resistor, each first element 62 preferably being a resistor.

Each first switch 64 comprises, for example, a transistor, such as a field-effect transistor. Each gate 64G of the transistor of a respective first switch 64 is connected to the output of each logic unit 42. The source 64S of said transistor is connected to a voltage line of predefined value, such as the value V_{DD}, and the drain 64D of said transistor is connected to a respective capacitor 63.

All the first elements 62 are arranged one after the other in the form of a conversion bridge 78, also known as a pop bridge.

The conversion units 61 are therefore arranged one after the other to form the conversion bridge 78. When each first element 62 comprises a respective capacitor 63, the conversion units 61 are connected in parallel with one another, between a first line at a first predefined voltage, such as the voltage V_{DD}, and a first complementary line at another voltage, called the pop voltage and noted Vₚₒₚ, corresponding to the intermediate value at the output of the conversion module 44.

For the conversion bridge 78, the number of capacitors 63 connected in parallel is then equal to the number of first elements 62 activated, in other words, to n−popcount XNOR(Wⱼ,xⱼ). The set of capacitors 63 of the conversion bridge 78 is therefore equivalent to a single capacitor (n−popcount XNOR(Wⱼ,xⱼ))*C₀ connected between the voltages V_{DD} and Vₚₒₚ.

The conversion module 44 also comprises a first resistor 65 of predefined impedance R, connected between the first complementary line to the voltage Vₚₒₚ and a predefined potential, such as an electrical ground GND. The first resistor 65 is included in the conversion bridge 78.

Thus, if the conversion bridge 78 is initially precharged to the first predefined voltage V_{DD}, the implementation of a calculation operation, in other words, the activation of a row 18 by its word line WL and the application of input activations on the complementary bit lines BL/BL_{B}, will generate the discharge of a capacitor equivalent to the capacitance (n−popcount XNOR(Wⱼ,xⱼ))*C₀ through the first resistor 65.

The intermediate value being the voltage Vₚₒₚ of the first complementary line connected both to the capacitors 63 of capacitance C₀ and to the first resistor 65 of impedance R, the variation over time of the intermediate value depends on a time constant equal to (n−popcount XNOR(Wⱼ,xⱼ))*RC₀.

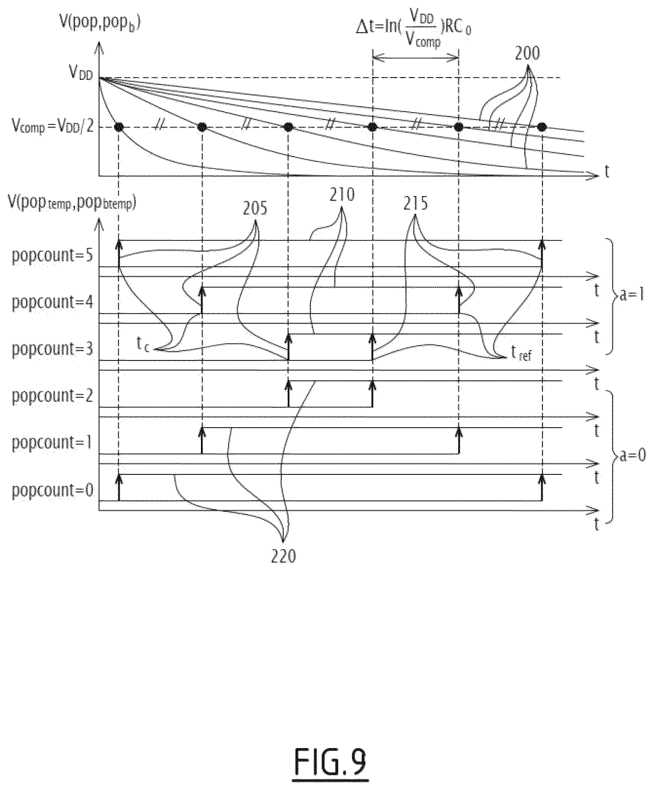

The variation over time of the voltage Vₚₒₚ in the example of FIG. 8 is represented for several values of popcount and n=5 on the curves 200 at the top of FIG. 9.

The acquisition unit 58 comprises, for example, a reference voltage generator 66. In the example of FIG. 8, the reference voltage generator 66 is in the form of a generation bridge 80, symmetrical relative to the conversion bridge 78 of the conversion module 44.

The reference voltage generator 66 then comprises a set of the same second elements 68 connected to each other and a set of second switches 70, the second elements 68 advantageously being identical to the first elements 62.

Each second element 68 is associated with the output of a respective logic unit 42, each second switch 70 being connected to the output of a respective logic unit 42 and configured to activate, or respectively inhibit, the corresponding second element 68 according to the high or low value at the output of the respective logic unit.

Each second switch 70 is inversely controlled relative to the first switch 64 of the converter module 44, which is connected to the output of the same respective logic unit 42.

In particular, if a logic “1” is calculated at the output of a logic unit 42, the respective second switch 70 is configured to activate the corresponding second element 68; and by extension if a logic “0” is calculated at the output of a logic unit 42, the respective second switch 70 is configured to inhibit the corresponding second element 68. This example of control logic for the second element 68 corresponds to the case where each second switch 70 includes an NMOS transistor. The skilled person will of course understand that the aforementioned control logic is inversed if each second switch 70 includes a PMOS transistor, the respective second switch 70 then being configured to activate the corresponding second element 68 if a logic “0” is calculated at the output of a logic unit 42, and by extension to inhibit the corresponding second element 68 if a logic “1” is calculated at the output of the logic unit 42. The number of activated second element(s) 68 is then equal to the result of the calculation popcount XNOR(Wⱼ,xⱼ).

The second element 68 and the corresponding second switch 70 form a generation unit 67 connected to the output of the logic unit 42.

To this end, in the example of FIG. 8, each second element 68 also comprises a capacitor 63, each second element 68 preferably being a capacitor 63. Advantageously, the capacitors 63 all have the same capacitance value C₀.

Alternatively, as will be described in more detail in the example of FIG. 15, each second element 68 comprises a resistor, each second element 68 preferably being a resistor.

Each second switch 70 comprises, for example, an inverter 69 and a transistor, such as a field-effect transistor. The transistor of the second switch 70 is advantageously of the same type as that of the first switch 64, in other words, presenting the same control logic.

The output of each logic unit 42 is then connected to a respective inverter 69, itself connected to the transistor of the corresponding second switch 70, said transistor then being connected to a respective capacitor 63.

Alternatively, not represented, each second switch 70 comprises only one transistor, such as a field-effect transistor, and in particular does not comprise an inverter. According to this alternative, the transistor of the second switch 70 presents a control logic inverse to that of the transistor of the first switch 64.

Each gate 70G of the transistor of a respective second switch 70 is connected to the output of each logic unit 42. The source 70S of said transistor is connected to a voltage line of predefined value, such as the value V_{DD}, and the drain 70D of said transistor is connected to a respective capacitor 63.

All the second elements 68 are arranged one after the other in the form of the generation bridge 80, also known as the bridge pop_{b}.

The generation units 67 are thus arranged one after the other to form the generation bridge 80. When each second element 68 comprises a respective capacitor 63, the generation units 67 are connected in parallel with each other, between a second line at a second predefined voltage, such as the voltage V_{DD}, and a second complementary line at another voltage, called the voltage pop_b and noted V_{pop_b}, corresponding to the reference value.

For the generation bridge 80, the number of capacitors 63 connected in parallel is then equal to the number of second elements 68 activated, in other words, popcount XNOR(Wⱼ,xⱼ). The set of capacitors 63 in the generation bridge 80 are therefore equivalent to a single popcount XNOR(Wⱼ,xⱼ)*C₀ capacitor connected between the voltages V_{DD} and V_{pop_b}.

The reference voltage generator 66 also comprises a second resistor 71, with a predefined impedance, advantageously identical to the impedance R of the first resistor 65.

The second resistor 71 is connected between the second complementary line to the voltage V_{pop_b} and a predefined potential, such as the electrical ground GND. The second resistor 71 is included in the generation bridge 80.

Thus, if the generation bridge 80 is initially precharged to the second predefined voltage V_{DD}, the implementation of a calculation operation, in other words, the activation of a row 18 by its word line WL and the application of input activations on the complementary bit lines BL/BL_{B} will generate the discharge of a capacitor equivalent to the capacitance of the popcount XNOR(Wⱼ,xⱼ)*C₀ capacitor through the second resistor 71.

The reference value being the voltage V_{pop_b} of the second complementary line connected both to the capacitors 63 of capacitance C₀ and to the second resistor 71 of impedance R, the variation over time of the reference value depends on a time constant equal to popcount XNOR(Wⱼ,xⱼ)*RC₀.

The comparison unit 60 comprises, for example, two comparators 72 and 74, namely a first comparator 72 and a second comparator 74.

The first comparator 72 is configured to transform the intermediate value into a square-wave signal popₜₑₘₚ with a change-of-state edge 205 at a characteristic time instant t_{c}, as illustrated in FIG. 9.

To this end, the first comparator 72 is configured to receive as input the intermediate value Vₚₒₚ and a comparison voltage V_{comp}. The comparison voltage V_{comp}, for example, is chosen to be equal to

$$\frac{{V}_{DD}}{2} .$$

During the discharge of the conversion bridge, when the intermediate value Vₚₒₚ falls below the comparison voltage V_{comp}, the first comparator 72 causes the square-wave signal popₜₑₘₚ to switch, passing, for example, to a value greater than its initial value, the change-of-state edge 205 being a rising edge.

The variation over time of the square-wave signal popₜₑₘₚ is represented for several popcount values and for n=5 on the curves 210 in FIG. 9.

For a given popcount value, the characteristic time instant to is then equal to

$$( n - popcount XNOR ( {W}_{j} , {x}_{j} ) ) * ln ( \frac{{V}_{DD}}{{V}_{comp}} ) {RC}_{0} ,$$

where ln represents the natural logarithm function.

Thus, a time difference Δt between two characteristic time instants to for two successive popcount values is

$$ln ( \frac{{V}_{DD}}{{V}_{comp}} ) {RC}_{0} .$$

A person skilled in the art will then observe that this time difference Δt is independent of the number of inputs “n” to the electronic circuit 10 and therefore independent of the size of the neuron. The accuracy of the square-wave signal popₜₑₘₚ generation is therefore independent of the neuron size.

The second comparator 74 is configured to transform the reference value into a square-wave signal popₜₑₘₚ with a change-of-state edge 215 at a reference time t_{ref} as illustrated in FIG. 9.

To this end, the second comparator 74 is configured to receive as input the reference value V_{pop_b} and the comparison voltage V_{comp}.

During discharge of the generation bridge 80, when the reference value V_{pop_b} falls below the comparison voltage V_{comp}, the second comparator 74 causes a switch of the square-wave signal popₜₑₘₚ, passing to a value higher than its initial value, the change-of-state edge 215 being, in other words, a rising edge.

The variation over time of the square-wave signal popₜₑₘₚ is represented for several popcount values and for n=5 on the curves 220 in FIG. 9.

For a given popcount value, the reference time t_{ref} is therefore equal to

$$popcount XNOR ( {W}_{j} , {x}_{j} ) * ln ( \frac{{V}_{DD}}{{V}_{comp}} ) {RC}_{0} .$$

Thus, a time difference Δt between two reference time instants t_{ref} for two successive popcount values is therefore also equal to

$$ln ( \frac{{V}_{DD}}{{V}_{comp}} ) {RC}_{0} .$$

The skilled person will then observe that this time difference Δt is independent of the number of inputs “n” to the electronic circuit 10 and therefore independent of the size of the neuron. The accuracy of the generation of the signal popbₜₑₘₚ is therefore independent of the neuron size.

The comparison unit 60 is then configured to compare the characteristic time instant t_{c} and the reference time instant t_{ref}.

In the example of FIG. 8, the comparison unit 60 also comprises a flip-flop 76, such as a D flip-flop (Data), in other words, a flip-flop including only one data input, denoted D. The input value D is copied to the output, noted Q, on each clock edge.

The input D of the flip-flop 76 is connected to the output of the first comparator 72 to receive the signal popₜₑₘₚ, and the clock of the flip-flop 76 is connected to the output of second comparator 74 to receive the signal popₜₑₘₚ. The output Q of the flip-flop 76 corresponds to the result “a” of the calculation operation.

If the characteristic time instant t_{c} is less than, in other words, earlier than, the reference time instant t_{ref}, then the value of the input D of the flip-flop 76 is already at the high value of the clock edge corresponding to the reference time instant t_{ref} so that the high value is then copied to the output Q of the flip-flop 76 at the reference time instant t_{ref}. In other words, in this case, the flip-flop 76 provides the high value representative of a logic “1” as the result, noted “a”, of the calculation operation, as illustrated on the right of FIG. 8.

Conversely, if the characteristic time instant t_{c} is greater than, in other words, later than, the reference time instant t_{ref}, then the value of the input D of the flip-flop 76 is still at the low value of the clock edge corresponding to the reference time instant t_{ref}, so that the low value is then copied to the output Q of the flip-flop 76 at the reference time instant t_{ref}. In other words, in this case, the flip-flop 76 provides the low value representative of a logic “0” as the result “a” of the calculation operation, as also illustrated on the right of FIG. 8.

In this example of FIGS. 8 and 9, it can be seen that:

$${t}_{c} < {t}_{ref} ⇔ popcount XNOR ( {W}_{j} , {x}_{j} ) > \frac{n}{2}$$

A logic “1” at the output of the flip-flop 76 corresponds to a popcount greater than n/2, in other words, the number of high values at the output of the logic units 42 is greater than the number of low values.

Conversely, a logic “0” at the output of the flip-flop 76 corresponds to a popcount less than n/2, in other words, the number of high values at the output of the logic units 42 is less than the number of low values.

Thus, the result of the operation performed by the neuron is defined as a function of a threshold Th. The result being a logic “1” if the number of high values is greater than the threshold Th. In the case described above, the threshold Th is equal to n/2.

When, as an optional addition, the electronic circuit 10 comprises the additional matrix 26 of memory cells 12, also known as the bias matrix 26, this bias matrix 26 allows to obtain a threshold Th different from n/2, as will now be described.

The bias matrix 26 comprises “b” columns 20 and “m” rows 18, in other words, the same number of rows 18 as the matrix 14. The “m” rows of the bias matrix 26 are each connected to the word line WL of the respective row of the matrix 14.

The memory cells 12 in the same column 20 of the bias matrix 26 share the same pair of complementary bit lines BL and BLb and the same source line SL.

The number of added columns “b” is typically even.

The addition of “b” bias columns generates b+1 possible different Th threshold values centered around n/2.

Similar to the columns 20 of the matrix 14, each column 20 of the bias matrix 26 is followed by a logic unit 42. Note “p” the number of column(s) 20 of the bias matrix 26 the output of which from the respective logic unit 42 corresponds to a logic “0”.

The number of logic “0”s obtained at the output of the logic units 42 of the columns 20 of the bias matrix 26 is configured by the weights W stored in the memory cells 12 of the bias matrix 26 being selected by the word line WL, and activated by the input signal “in” fed to the selected cell 12 via the associated bit lines BL and BLb.

The conversion module 44 and the reference voltage generator 66 are extended to take into account the outputs of the additional logic units 42 of each column 20 of the bias matrix 26. In other words, the conversion module 44 then comprises a total of n+b first elements 62 and n+b first switches 64, and the reference voltage generator 66 comprises n+b second elements 68 and n+b second switches 70, when the reference voltage generator 66 comprises the generation bridge 80.

Each first element 62 is connected to a respective first switch 64 and each second element 68 is connected to a respective second switch 70, each switch 64, 70 activating or inhibiting the element 62, 68 as described above. Each first element 62, and respectively each second element 68, are according to this optional addition with the bias matrix 26 identical to the first 62, and respectively the second 68, elements described for the previous case without bias matrix.

The number of first elements 62 activated in the conversion module 44 is then equal to n−popcount XNOR(Wⱼ,xⱼ)+p.

Thus, if the conversion bridge 78 is initially precharged to the first predefined voltage V_{DD}, the implementation of a calculation operation, in other words, the activation of a row 18 by its word line WL and the application of input activations on the complementary bit lines BL/BL_{B}, will generate the discharge of a capacitor equivalent to the capacitance (n−popcount XNOR(Wⱼ,xⱼ)+p)*C₀ through the first resistor 65.

For a given popcount value, the characteristic time instant t_{c} of the popₜₑₘₚ supplied by the first comparator 72 is therefore equal to

$$( n - popcount XNOR ( {W}_{j} , {x}_{j} ) + p ) * ln ( \frac{{V}_{DD}}{{V}_{comp}} ) {RC}_{0} .$$

The number of second elements 68 activated in the reference voltage generator 66 is therefore equal to popcount XNOR(Wⱼ,xⱼ)+b−p.

Thus, if the generation bridge 80 is initially precharged to the second predefined voltage V_{DD}, the implementation of a calculation operation, in other words, the activation of a row 18 by its word line WL and the application of input activations on the complementary bit lines BL/BL_{B} will generate the discharge of a capacitor equivalent to the capacitance (popcount XNOR(Wⱼ,xⱼ)+b−p)*C₀ through the second resistor 71.

For a given popcount value, the reference time instant t_{ref} of the signal pop_{btem} supplied by the second comparator 74 is therefore equal to

$$( popcount XNOR ( {W}_{j} , {x}_{j} ) + b - p ) * ln ( \frac{{V}_{DD}}{{V}_{comp}} ) {RC}_{0} .$$

By analogy with the operation described above, it can be deduced that a characteristic time t_{c} less than the reference time t_{ref}, and consequently an output Q of the flip-flop 76 representing a logic “1” is equivalent to:

$${t}_{c} < {t}_{réf} ⇔ popcount XNOR ( {W}_{j} , {x}_{j} ) > \frac{n}{2} - \frac{b}{2} + p$$

A logic “1” at the output of the flip-flop 76 corresponds to a popcount greater than

$$\frac{n}{2} - \frac{b}{2} + p .$$

Conversely, a logic “0” at the output of the flip-flop 76 corresponds to a popcount less than

$$\frac{n}{2} - \frac{b}{2} + p .$$

Thus, when, as an optional addition, the electronic circuit 10 also comprises the bias matrix 26, the threshold Th is

$$\frac{n}{2} - \frac{b}{2} + p .$$

The threshold Th then depends on the number “b” of bias columns and the number “p” of logic “0”s at the output of the logic units 42 of each bias column.

For

$$p = \frac{b}{2} ,$$

in other words, if half of the outputs of the logic units 42 of the bias columns correspond to a logic “0” and the other half to a logic “1”, the threshold Th is equal to n/2. The result therefore obtained is equivalent to an electronic circuit 10 not comprising the bias matrix 26.

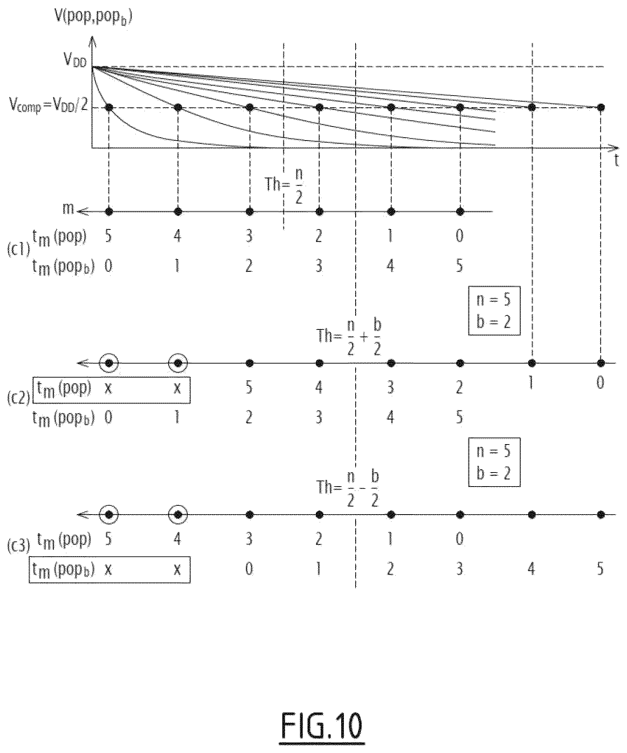

FIG. 10 represents various possible thresholds Th for n=5 and b=2. In the example of FIG. 10, different possible values for the characteristic time instant t_{c} are indicated on a line marked tₘ(pop), and similarly different possible values for the reference time instant t_{ref} are indicated on a line marked tₘ(pop_{b}).

In the configuration (c1), the electronic circuit 10 does not comprise the bias matrix 26. We therefore have

$$Th = \frac{n}{2} .$$

In the configuration (c2), the bias matrix 26 includes two columns 20 of memory cells 12. The two memory cells 12 selected by the word line WL are both configured to obtain a logic “0” at the output of their respective logic unit 42, in other words, p=2. Thus, the characteristic time instant t_{c} obtained with bias for a given popcount is offset by 2*Δt relative to the characteristic time instant t_{c} obtained without bias for the same popcount, where Δt represents the time difference between two characteristic time instants t_{c} for two successive popcount values, such as for example

$$ln ( \frac{{V}_{DD}}{{V}_{comp}} ) {RC}_{0} .$$

This 2*Δt offset is represented by the box for configuration (c2) in FIG. 10. Therefore,

$$T h = \frac{n}{2} - \frac{b}{2} + p = \frac{n}{2} + 1.$$

The characteristic time instant t_{c} corresponding to the threshold Th is represented by the dotted line running up to the chronogram.

In the configuration (c3), the bias matrix 26 also includes two columns 20 of memory cells 12. The two memory cells 12 selected by the word line WL are here both configured to output a logic “1” from their respective logic units 42, in other words, p=0. Thus, the reference time instant t_{ref} obtained with bias for a given popcount is offset by 2*Δt relative to the reference time t_{ref} obtained without bias for the same popcount, where Δt represents the aforementioned time difference. This 2*Δt offset is represented by the box for configuration (c3) in FIG. 10. Therefore

$$Th = \frac{n}{2} - \frac{b}{2} + p = \frac{n}{2} + 1.$$

The reference time instant t_{ref} corresponding to the threshold Th is represented by the dotted line running up to the chronogram.

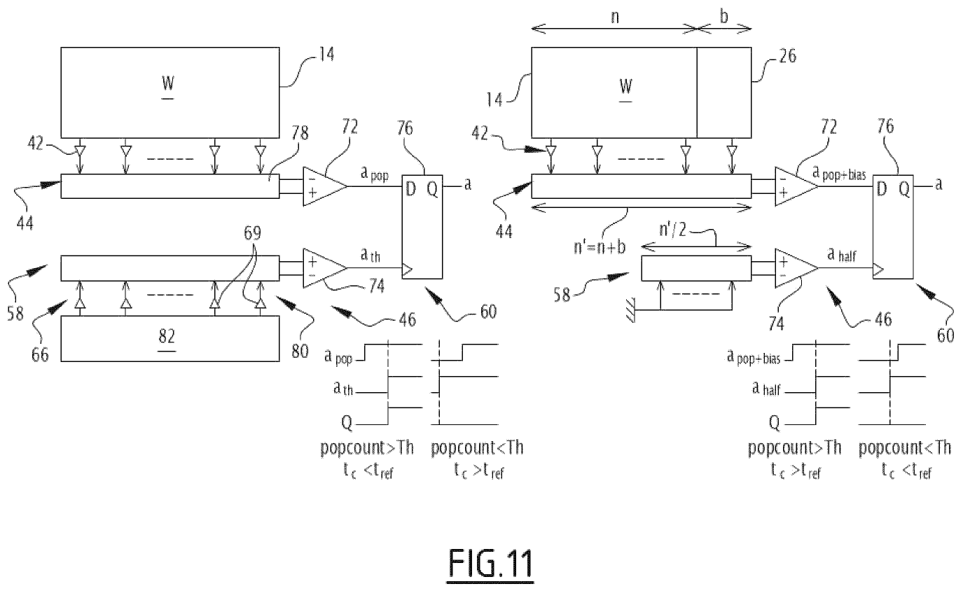

The second and third embodiments of the electronic circuit 10 presenting a bias will now be described, with reference to FIG. 11.

The second and third embodiments differ from the first embodiment concerning the reference voltage generator 66, so only the differences between the first embodiment described above and the second and third embodiments of FIG. 11 will be described below.

In the second embodiment illustrated on the left of FIG. 11, the reference voltage generator 66 comprises the generation bridge 80 and a complementary matrix 82 of memory cells 12. The difference between this second embodiment and the first embodiment described above is that the generation bridge 80 is not connected to the output of the logic units 42, the generation bridge 80 according to this second embodiment being connected to the output of said complementary matrix 82. The second switches 70 are therefore not controlled by the outputs of these logic units 42, but by the complementary matrix 82.

The complementary matrix 82 is configured to provide “n” outputs to the second switches 70, “n” for memory, being the number of columns in the matrix 14. Each output can take a high value corresponding to a logic “1” or a low value corresponding to a logic “0”.

The complementary matrix 82 comprises “n” columns 20 like the matrix 14 and at least one row 18. Each memory cell 12 in the same row 18 shares the same word line WL. The memory cells 12 in the same column 20 share the same pair of complementary bit lines BL and BLb and the same source line SL.

The number of logic “1”s and logic “0”s at the output of the complementary matrix 82 defines the threshold Th. The number of “0”s included in the series of bits at the output of the complementary matrix 82 is noted “r”. Preferably “r” is between

$$\frac{n}{2} - 10 \% and \frac{n}{2} + 10 \% .$$

The number of rows 18 of the complementary matrix 82 is therefore equal to the number of desired threshold values. The word line WL connecting the row of the complementary matrix 82 storing the desired threshold weights activates the memory cells 12 of said row 18.

The second switches 70 according to this second embodiment are identical to those described above for the first embodiment, and include, for example, the inverters 69 visible in FIG. 11.

For example, each second switch 70 is configured to activate the corresponding second element 68 if the output of the complementary matrix 82 is representative of a logic “0” and inhibit the corresponding element if said output is representative of a logic “1”.

Thus, if the generation bridge 80 is initially precharged to V_{DD}, the implementation of a calculation operation, in other words, the activation of a row 18 by its word line WL and the application of the input activations on the complementary bit lines BL/BL_{B} will generate the discharge of a capacitor equivalent to the capacitance r*C₀ through the resistor R.

The reference time instant t_{ref} of the signal aₜₕ supplied by the second comparator 74, according to this second embodiment is then equal to

$$r * ln ( \frac{{V}_{D D}}{{V}_{c o m p}} ) R {C}_{0} .$$

The reference time instant t_{ref} obtained is compared by the flip-flop 76 with the characteristic time instant t_{c} of the signal supplied by the first comparator 72, noted here as aₚₒₚ and obtained in the absence of the bias matrix 26, in other words,

$${t}_{c} = ( n - popcount XNOR ( {W}_{j} , {x}_{j} ) ) * ln ( \frac{{V}_{D D}}{{V}_{c o m p}} ) R {C}_{0} .$$

According to the previous reasoning, we have:

$${t}_{c} < {t}_{r {e}^{'} f} ⇔ popcount XNOR ( {W}_{j} , {x}_{j} ) > n - r$$

The output signal of the flip-flop 76 is therefore representative of a logic “1” if the popcount XNOR(Wⱼ,xⱼ)>n−r, and the output signal of the flip-flop 76 is representative of a logic “0” if the popcount XNOR(Wⱼ,xⱼ)<n−r.

The threshold Th is therefore n−r.

According to one alternative, each second switch 70 is configured to activate the corresponding second element 68 if the output of the complementary matrix 82 is representative of a logic “1” and inhibit the corresponding second element 68 if the output is representative of a logic “0”.

Thus, if the generation bridge 80 is initially precharged to V_{DD}, the implementation of a calculation operation, in other words, the activation of a row 18 by its word line WL and the application of the input activations on the complementary bit lines BL/BL_{B} will generate the discharge of a capacitor equivalent to the capacitance (n−r)*C₀ through the resistor R.

The output signal of the flip-flop 76 is therefore representative of a logic “1” if the popcount XNOR(Wⱼ,xⱼ)>r, and the output signal of the flip-flop 76 is representative of a logic “0” if the popcount XNOR(Wⱼ,xⱼ)<r.

The threshold Th is therefore “r”.

A person skilled in the art will observe that the complementary matrix 82 then allows the generation bridge 80 to be controlled independently of the matrix 14, thus allowing the desired threshold value Th to be generated, without having a bias matrix 26 associated with the matrix 14 of the memory cells 12. This requires, however, that each row of the complementary matrix 82 corresponds to a different threshold to cover the necessary

$$\frac{n}{2} \pm 10 \%$$

biases.

In the third embodiment illustrated on the right of FIG. 11, the electronic circuit 10 comprises the additional bias matrix 26, the latter comprising “b” columns 20.

The reference voltage generator 66 comprises a plurality of generation units 67. In the example of FIG. 11, the reference voltage generator 66 comprises

$$\frac{n + b}{2}$$

generation units 67.

Each generation unit 67 presents one input, and the inputs of all the conversion units are connected to the same potential, for example to the electrical ground GND. Each generation unit 67 according to this third embodiment is identical to a respective generation unit 67 described according to the first embodiment.

The generation units 67 are connected in parallel between the voltage V_{DD} and the voltage V_{pop_b}.

In the case where the first elements 62 of the conversion module 44 are capacitors 63, the voltage generator also comprises a resistor R.

Thus, the generation bridge 80 is initially precharged to V_{DD}, the implementation of a calculation operation will generate the discharge of a capacitor equivalent to the capacitance

$$\frac{n + b}{2} * {C}_{0}$$

through the resistor R.

The reference time instant t_{ref} of the signal a_{half} supplied by the second comparator 74 according to this third embodiment is therefore equal to

$$\frac{n + b}{2} * ln ( \frac{{V}_{D D}}{{V}_{c o m p}} ) R {C}_{0} .$$

The reference time instant t_{ref} obtained is compared by the flip-flop 76 with the characteristic time instant to of the signal supplied by the first comparator 72, the latter being noted here a_{pop+bias} and obtained by considering that “p” is the number of bias columns the output of which the respective logic unit 42 corresponds to a logic “0”, in other words

$${t}_{c} = ( n - popcount XNOR ( {W}_{j} , {x}_{j} ) + p ) * ln ( \frac{{V}_{D D}}{{V}_{c o m p}} ) R {C}_{0} .$$

According to the previous reasoning, we have:

$${t}_{c} < {t}_{r e f} ⇔ popcount XN OR ( {W}_{j} , {x}_{j} ) > \frac{n}{2} + p - \frac{b}{2}$$

A threshold is therefore

$$Th = \frac{n}{2} + p - \frac{b}{2} .$$

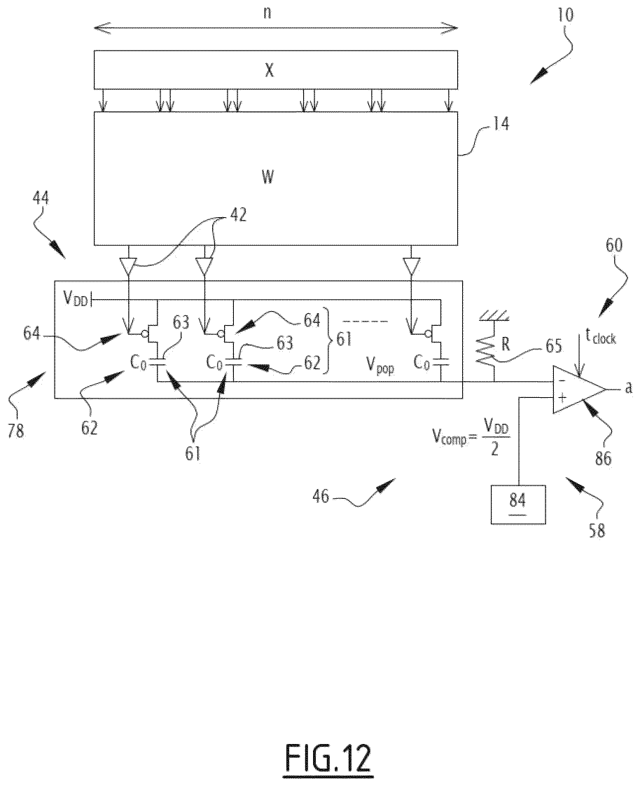

A fourth embodiment of the electronic circuit 10 will now be described, with reference to FIG. 12. Only the differences between the first and fourth embodiments are described below.

According to FIG. 12, the acquisition unit 58 comprises a voltage source 84 supplying a fixed comparison voltage V_{comp}, of constant value, at the input of the comparison unit 60. Preferably, the comparison voltage V_{comp} is equal to V_{DD}/2.

In the example of FIG. 12, the comparison unit 60 comprises a comparator 86 with a clock reference, hereinafter referred to as clocked comparator 86, which takes as input the intermediate value from the conversion module 44 at its negative terminal and the comparison voltage V_{comp} from the acquisition unit 58, and in particular from the voltage source 84, at its positive terminal, and generates as output a signal “a” representative of a logic “1” or a logic “0”.

The intermediate value is the conversion bridge voltage 78, noted Vₚₒₚ, the variation of which over time depends on a time constant equal to (n−popcount XNOR(Wⱼ,xⱼ))*RC₀.

The characteristic time instant to is defined as the instant at which the voltage Vₚₒₚ is less than the comparison voltage V_{comp}:

$${V}_{pop} < {V}_{comp} ⇔ t > {t}_{c} , with {t}_{c} = ( n - popcount XNOR ( {W}_{j} , {x}_{j} ) ) ln ( \frac{{V}_{D D}}{{V}_{c o m p}} ) R {C}_{0}$$

The clock edge of the clocked comparator 86 is fixed at a clock reference t_{clock} configured so that if t_{c}<t_{clock}, the neural calculation result is 1, therefore the signal “a” at the output of the clocked comparator 86 is representative of a logic “1”, and if tₑ>t_{clock}, the neural calculation result is 0, therefore the signal “a” at the output of the clocked comparator 86 is representative of a logic “0”.

The value of the clock reference t_{clock} then allows to define a fixed threshold Th, such as:

$${t}_{c} < {t}_{c l o c k} ⇔ popcount > Th , Th = n - \frac{{t}_{c l o c k}}{ln ( \frac{{V}_{D D}}{{V}_{c o m p}} ) R {C}_{0}}$$

For example, to have a threshold Th of n/2, the clock edge is fixed at the clock reference

$${t}_{clock} = \frac{n}{2} ln ( \frac{{V}_{DD}}{{V}_{réf}} ) R {C}_{0} .$$

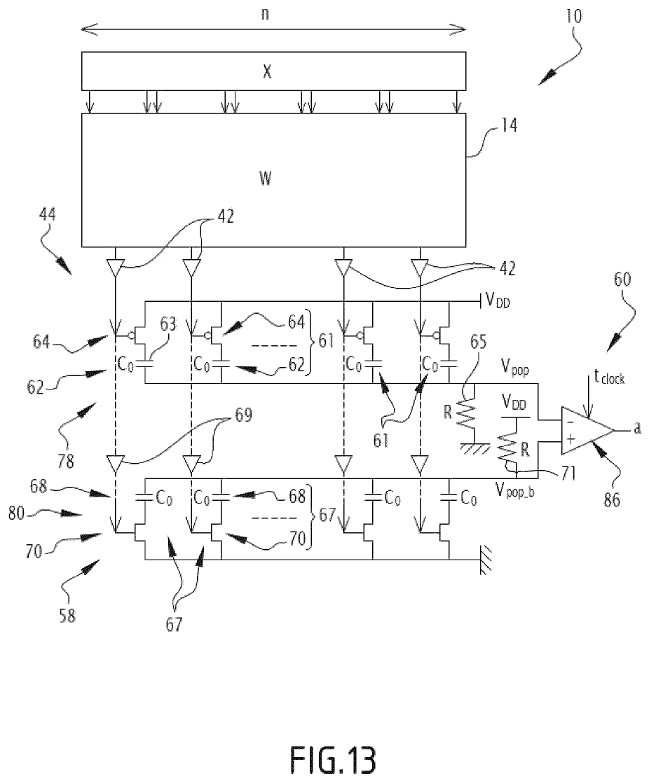

A fifth embodiment of the electronic circuit 10 will now be described, with reference to FIG. 13. Only the differences between the fourth and fifth embodiments are described below.

In the example of FIG. 13, the reference voltage generator 66 is the generation bridge 80, symmetrical to the conversion bridge 78 of the conversion module 44.

The reference voltage generator 66 is then obtained via a set of the same second elements 68 connected together and a set of second switches 70, the second elements 68 being identical to the first elements 62 of the set of conversion modules 44. The person skilled in the art will note that in the example of FIG. 13, the second switches 70 typically have an inversed control logic relative to the second switches 70 in the example of FIG. 8. In the example of FIG. 8, each second switch 70 typically includes a NMOS transistor; and in the example of FIG. 13, each second switch 70 typically includes a PMOS transistor.

In the example of FIG. 13, each first element 62 of the conversion module 44 comprises a capacitor 63 of capacitance C₀, and each second element 68 comprises a capacitor 63 of capacitance C₀.

The reference voltage generator 66 further comprises the second resistor 71 of impedance R, identical to the first resistor 65 of the conversion module 44 and connected to the voltage V_{DD}.

Thus, if the generation bridge 80 is initially discharged, the implementation of a calculation operation, in other words, the activation of a row 18 by its word line WL and the application of input activations on the complementary bit lines BL/BL_{B} will generate the charge of a capacitor of equivalent capacitance (n−popcount XNOR(Wⱼ,xⱼ))*C₀ through the second resistor 71 of impedance R.

The reference value being the voltage V_{pop_b} of the generation bridge 80, the variation over time of the reference value depends on a time constant equal to (n−popcount XNOR(Wⱼ,xⱼ))*RC₀. This time constant is equal to the time constant of the variation of the intermediate value supplied by the conversion module 44.

The voltages Vₚₒₚ and V_{pop_b} present a point of intersection for a voltage value of the order of

$$\frac{{V}_{DD}}{2} .$$

The clocked comparator 86 takes as input the intermediate value Vₚₒₚ from the conversion module 44 at its negative terminal and the reference value V_{pop_b} at its positive terminal and generates as output a signal “a” representative of a logic “1” or a logic “0”.

The characteristic time instant to is defined as the instant from which the voltage Vₚₒₚ is less than the reference voltage V_{pop_b}:

$${V}_{pop} < {V}_{popb} ⇔ t > {t}_{c} , \\ with {t}_{c} = ( n - popcount XNOR ( {W}_{j} , {x}_{j} ) ) ln ( 2 ) {RC}_{0}$$

The clock edge of the clocked comparator 86 is fixed to the clock reference t_{clock}, configured so that if t_{c}<t_{clock}, the neural calculation result is 1, then the signal “a” at the output of the clocked comparator 86 is representative of a logic “1”, and if t_{c}>t_{clock}, the neural calculation result is 0, then the signal “a” at the output of the clocked comparator 86 is representative of a logic “0”.

The value of the clock reference t_{clock} allows to define a fixed threshold Th such that:

$${t}_{c} < {t}_{c l o c k} ⇔ popcount > Th , Th = n - \frac{{t}_{clock}}{ln ( 2 ) R {C}_{0}}$$

For example, to have a threshold Th of n/2, the clock edge is fixed at the clock reference

$${t}_{clock} = \frac{n}{2} ln ( 2 ) R {C}_{0} .$$

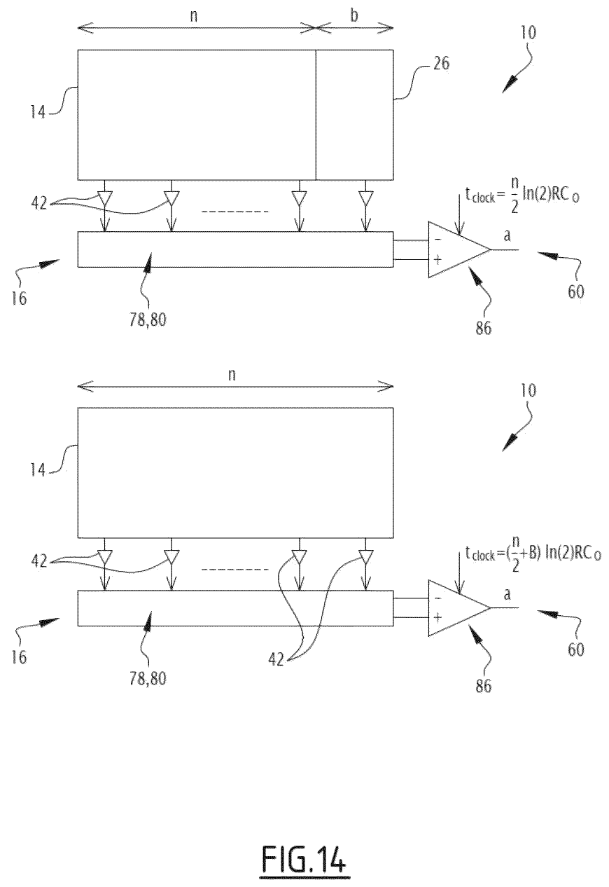

The sixth and seventh embodiments of an electronic circuit 10 with a bias for offsetting the threshold value Th, and with a comparison unit 60 comprising the clocked comparator 86 will now be described, with reference to FIG. 14.

Only the differences between the fifth embodiment described above and the sixth and seventh embodiments of FIG. 14 will therefore be described below.

In the sixth embodiment illustrated at the top of FIG. 14, the electronic circuit 10 comprises the bias matrix 26.

The bias matrix 26 comprises “b” columns 20 of memory cells 12.

The clock edge of the clocked comparator 86 is fixed and has the clock reference t_{clock}. Preferably, the clock reference t_{clock} is defined such that the threshold Th, in the absence of bias is n/2. In other words,

$${t}_{clock} = \frac{n}{2} ln ( 2 ) R {C}_{0} .$$

The reference voltage generator 66 is, for example, the generation bridge 80, symmetrical to the conversion bridge 78 of the conversion module 44, but on charge.

The reference value being the voltage V_{pop_b} of the generation bridge 80, the variation over time of the reference value V_{pop_b} then depends on a time constant equal to (n−popcount XNOR(Wⱼ,xⱼ)+p)*RC₀. As a reminder, “p” is the number of bias columns the output of which from the respective logic unit 42 corresponds to a logic “0”. This time constant is equal to the time constant of the variation of the intermediate value Vₚₒₚ supplied by the conversion module 44.

From this is deduced, the characteristic time instant t_{c}:

$${V}_{pop} < {V}_{popb} ⇔ t > {t}_{c} , \\ with {t}_{c} = ( n - popcount XNOR ( {W}_{j} , {x}_{j} ) + p ) ln ( 2 ) R {C}_{0} \\ {t}_{c} < {t}_{clock} ⇔ popcount > Th , Th = n + p - \frac{{t}_{clock}}{ln ( 2 ) R {C}_{0}}$$

Thus, if a clock reference

$${t}_{clock} = \frac{n}{2} ln ( 2 ) R {C}_{0} ,$$

the threshold Th is

$$\frac{n}{2} + p$$

The bias matrix 26 therefore allows different threshold values to be obtained as a function of the number “p” of bias columns the output of which from the respective logic unit 42 corresponds to a logic “0”. We therefore have 0≤p≤b, which corresponds to b+1 possible threshold Th values centered around n/2.

In the seventh embodiment illustrated at the bottom of FIG. 14, the clock signal of the clocked comparator 86 is the variable

$${t}_{clock} = ( \frac{n}{2} + B ) ln ( 2 ) R {C}_{0} .$$

The value B is a natural integer and allows a variable threshold Th to be obtained, depending on the value B:

$$Th = \frac{n}{2} + B .$$

### Preferably

$$- \frac{n}{2} * 10 \% \leq B \leq \frac{n}{2} * 10 \% .$$

The embodiments of the electronic circuit 10 described above are not limiting and are given by way of example only. Any technically possible combination of the features described in the preceding and following examples also corresponds to the invention.

In particular, the comparison unit 60 comprises, for example, the clocked comparator 86; or even the flip-flop 76 as well as the first and second comparators 72 and 74.

Similarly, the acquisition unit 58 comprises, for example, the reference voltage generator 66 as represented in FIG. 8; or even the voltage source 84 supplying the fixed comparison voltage V_{comp} to the input of the comparison unit 60 as represented in FIG. 12.

The reference voltage generator 66 is, for example, performed by the generation bridge 80, symmetrical to the conversion bridge 78 of the conversion module 44, the generation bridge 80 being controlled by the matrix 14, as represented in FIG. 8; or even by the generation bridge 80 controlled by the complementary matrix 82, as illustrated on the left of FIG. 11.

In addition, the generation bridge 80, symmetrical to the conversion bridge 78, can be configured to be equivalent to the charging or discharging of a capacitor.

In the case where the comparator unit 60 comprises the flip-flop 76, a bias can be added to the threshold Th through the addition of the bias matrix 26 or via the complementary matrix 82.

The reference voltage generator 66 may also comprise a half-bridge formed by

$$\frac{n + b}{2}$$

generation units 67 if the bias matrix 26 is present.

In the case where the comparison unit 60 comprises a clocked comparator 86, the threshold Th can be modified by the presence of a bias by the addition of the bias matrix 26 if the clock time of the clocked comparator 86 is fixed, or even via the variation of the clock time as a function of the desired bias.

The electronic circuit 10 according to the invention therefore comprises the comparison module 46 defined according to any technically possible combinations of the features described above.

A further alternative which can be combined with the above-described embodiments is illustrated by an eighth embodiment with reference to FIG. 15. Only the differences between the fifth embodiment and the eighth embodiment will be described below.

In the example of FIG. 15, the conversion units 61 of the conversion module 44 are connected in series.

Each conversion unit 61 comprises the first element 62 and the first switch 64 connected in parallel.

Each first element 62 comprises a resistor 88 of resistance R₀ and each first switch 64 comprises a switch 90 configured to activate or inhibit the corresponding resistor 88.

In particular, if a logic “0” is calculated at the output of a logic unit 42, the respective first switch 64 is configured to activate the corresponding first element 62, therefore the switch 90 is open; and if a logic “1” is calculated at the output of a respective logic unit 42, the respective first switch 64 is configured to inhibit the corresponding first element 62, therefore the switch 90 is closed.

The resistor 88 located at the output of the first column 20 is connected to the electrical ground GND, and the resistor 88 located at the output of the last column 20 is connected to the input of the comparison unit 60.

The conversion module 44 also comprises a first capacitor 92 of capacitance C connected between the input of the comparison unit 60 and the potential V_{DD}.

Thus, if the conversion bridge 78 is initially precharged to the potential V_{DD}, the implementation of a calculation operation, in other words, the activation of a row 18 by its word line WL and inputs on the complementary bit lines BL/BL_{B} will generate the discharge of the capacitor of capacitance C through a resistor of equivalent resistance (n−popcount XNOR(Wⱼ,xⱼ))*R₀.

The intermediate value being the voltage Vₚₒₚ of the conversion bridge 78, the variation over time of the intermediate value depends on a time constant equal to (n−popcount XNOR(Wⱼ,xⱼ))*CR₀.

The resistors 88 of the first elements 62 forming the conversion bridge 78 are connected in series between the electrical ground GND and the voltage Vₚₒₚ.

Similarly, each second element 68 of the reference voltage generator 66 forming the generation bridge 80, symmetrical to the conversion bridge 78 of the conversion module 44, comprises the resistor 88 of resistance R₀ and each second switch 70 comprises the switch 90 in parallel with the resistor 88.

The resistors 88 of the second elements 68 forming the generation bridge 80 are connected in series between a potential V_{A} and the voltage V_{pop_b}.

The reference voltage generator 66 further comprises a second capacitor 94 of capacitance C connected between the voltage V_{pop_b} and a potential V_{B}.

The values of the potentials V_{A} and V_{B}, as well as the control logic of the second switches 70, are defined as a function of the charge or discharge of the second capacitor 94 during implementation of a neural calculation.

Thus, all other things being equal, all the above examples are technically possible using the resistors 88 as first elements 62, and where applicable the second elements 68, instead of the capacitors 63.

The calculation steps described above remain valid when replacing C₀ by R₀, and C by R respectively.

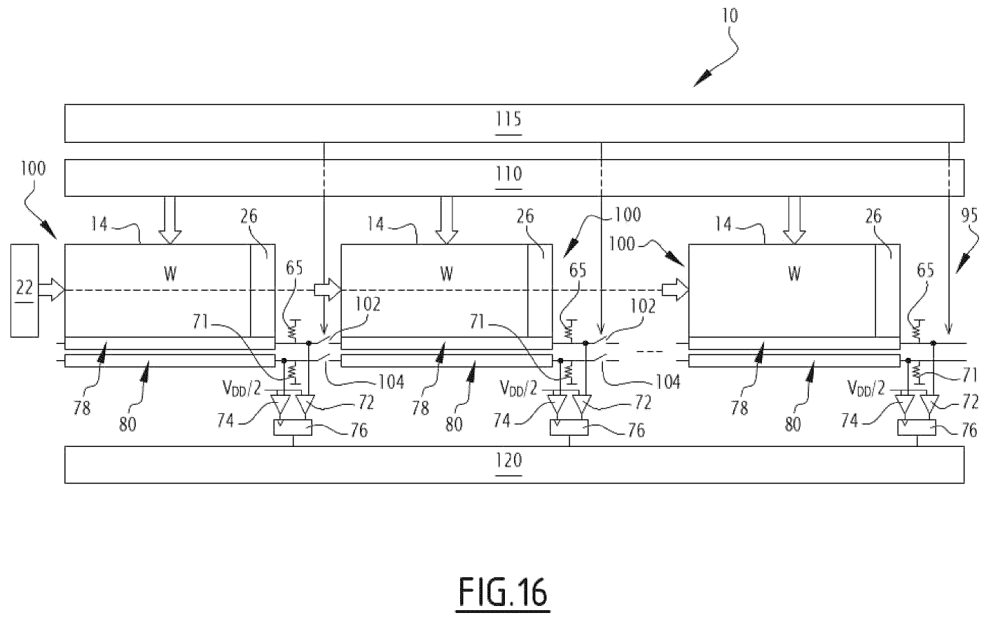

The great advantage that the invention presents, is the possibility of implementing a binary neuron the accuracy of which is independent of the size of the neuron. This allows very large neurons to be implemented with very good accuracy, with just in counterpart a possibly longer calculation time. As the sizes of the implemented neurons can vary from one neural network architecture to another and even from one layer to another, the electronic circuit 10 according to the invention optionally and advantageously presents a sub-bank architecture 95 in the form of a row of neural nodes where each neural node 100 is configured to implement a respective neuron and where the neurons have minimum sizes of “x” inputs, as illustrated in FIG. 16.

In the example of FIG. 16, each neural node 100 comprises the matrix 14 of resistive memory cells 12 for storing weights, and optionally the bias matrix 26; the conversion bridge 78 and the associated first resistor 65, and optionally the generation bridge 80 and the associated second resistor 71; the first and second comparators 72, 74 and the flip-flop 76.

The neural nodes 100 are then able to be connected to each other by the first switches 102 to connect the conversion bridges 78 in series, and optionally by the second switches 104 to put the generation bridges 80 in series, in order to implement larger neurons. The connection between two neural nodes 100 of minimum size “x” is simple, as it is only necessary to connect their conversion bridges 78, and respectively their generation bridges 80, to each other to implement a neuron of size 2x. However, only one discharge resistor 65, 71 per bridge 78, 80 is to be connected.

The control of such a neural node 100 architecture is straightforward, as shown in FIG. 10, with common control of the word lines WL via the first controller 22; an input activation register 110 able to store the inputs; a register 115 for controlling connections between the neural nodes 100, then able to control the first and second switches 100, 102; and an output register 120 retrieving output activations from all the neural nodes 100 in parallel.

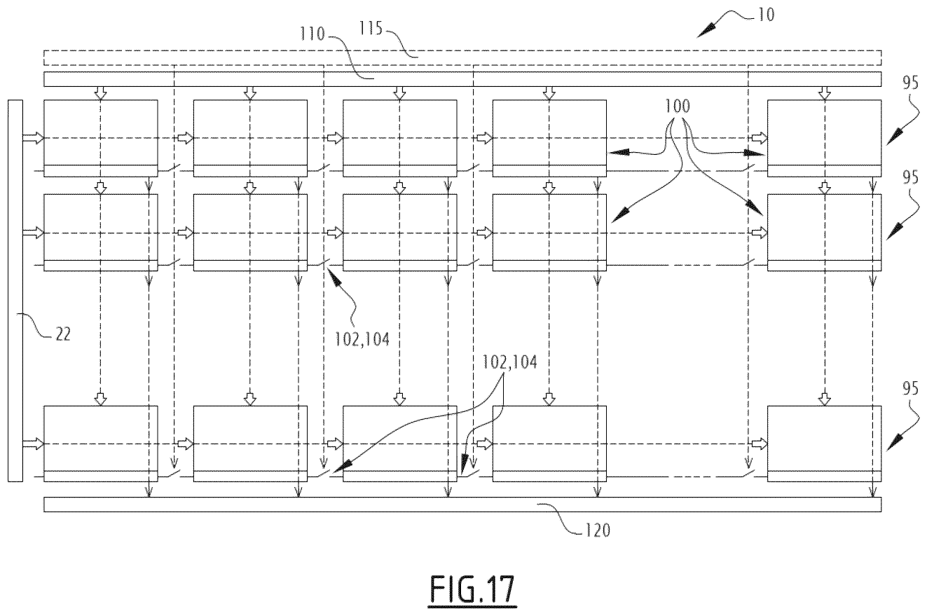

FIG. 17 illustrates the architecture of a bank built from several sub-banks 95, each sub-bank 95 being of the type previously described opposite FIG. 16. The sub-banks 95 share the same input activation register 110 and the same register 115 for controlling the connections between the neural nodes 100, and the outputs of the neural nodes 100 are multiplexed to be captured by the common output register 120 retrieving the output activations. This control can be complexified for greater control granularity.

The invention then offers great flexibility in mapping the weights and the neurons:
one neuron per neural node 100 if the neurons are small;
one neuron on several neural nodes 100 if the number of neuron inputs is too high to use a single neural node 100;
the same neurons with several inputs in parallel by duplicating the weights on several neural nodes 100.

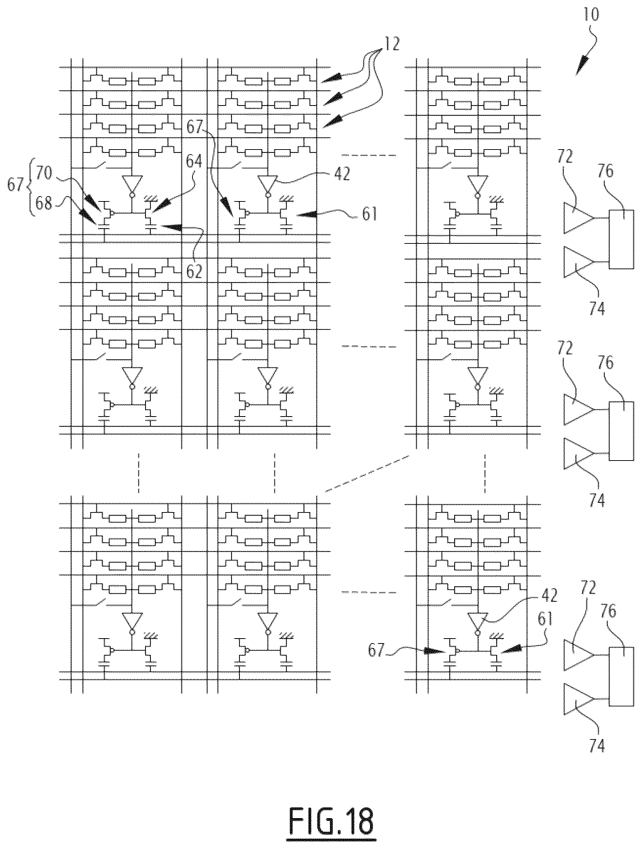

Another alternative consists in integrating the first elements 62 and the switches 64, and respectively the second elements 68 and the switches 70, directly within the matrix 14 of memory cells 12, as illustrated in FIG. 18. It should be noted that precharging the ends of the first elements 62, respectively the second elements 68, for example in the form of capacitors 63, can be done simply by applying a signal at the potential GND, followed by a signal at the potential V_{DD} on the common source line, which will allow the internal nodes of the first switches 64, followed by those of the second switches 70 to be precharged.

It is thus conceivable that the electronic circuit 10 according to the invention allows to implement a binary neural network with resistive memory cells 12 and for larger neurons, in other words, with a higher number of inputs.

1. An electronic circuit suitable for implementing computing operations each providing a binary output, the circuit comprising:
word lines;
pairs of complementary bit lines;
source lines;
a set of memory cells organized according to a matrix including rows and columns, the memory cells of a same row being selectable by a word line, the memory cells of a same column being connected to a pair of complementary bit lines and to a source line;
each memory cell comprising two memristors and two switches, each memristor being connected to the same source line and to a respective switch, each memristor respectively storing a weight or the inverse of the same weight by respectively presenting first and second different resistance values; the switches being connected, for their activation, to a respective word line and connected respectively to a pair of complementary bit lines;
a reading device implemented during each calculation operation, the reading device comprising:
a logic unit for each column, each logic unit comprising an input terminal connected to a respective source line for receiving an input value, the logic unit being configured to perform a logic operation presenting a switching between a low value and a high value depending solely on the value of the input of the logic unit which is connected to the source line during said calculation operation,
wherein the reading device further includes:
a conversion module configured to convert a number of high or low values at the output of the logic units into an intermediate value dependent on said number of high or low values at the output of the logic units, the intermediate value is an electrical value, the variation of which over time depends on a time constant, and the value of the time constant is a function of the number of high or low values at the output of the logic units, the conversion module including a set of same elements connected together and a set of switches, each element being associated with the output of a respective logic unit, each switch being connected to the output of a respective logic unit and configured to activate, or respectively inhibit, the corresponding element according to the high or low value at the output of the respective logic unit, and the value of the time constant depending on the number of elements activated, and
a comparison module configured to compare the intermediate value with a reference value and to output a one-bit digital signal, depending on the comparison and corresponding to the output of the electronic circuit, the output signal being representative of the result of the calculation operation.

2. The electronic circuit according to claim 1, wherein the value of the time constant is directly proportional to the number of high or low values at the output of the logic units.

3. The electronic circuit according to claim 1, wherein the value of the time constant is equal to the product of a capacitance and a resistance, one from among the capacitance and the resistance being predefined, and the other from among the capacitance and the resistance depending on the number of high or low values at the output of the logic units.

4. The electronic circuit according to claim 1, wherein each element is a resistor or a capacitor.

5. The electronic circuit according to claim 1, wherein the set of same elements is placed between a first supply potential and an intermediate node, and the conversion module further includes a complementary element placed between the intermediate node and a second supply potential.

6. The electronic circuit according to claim 5, wherein when each element is a capacitor, the complementary element is a resistor;
wherein when each element is a resistor, the complementary element is a capacitor.

7. The electronic circuit according to claim 1, wherein the comparison module is configured to transform the intermediate value into a square-wave signal with a change-of-state edge at a characteristic time instant, the characteristic time instant then being compared with a reference time instant associated with the reference value, and the signal representative of the result of the calculation operation then depending on said comparison.

8. The electronic circuit according to claim 5, wherein the intermediate value is transformed into the square-wave signal via a comparator.

9. The electronic circuit according to claim 6, wherein the comparison module includes the comparator and a comparison voltage generator, and the comparator is able to compare the generated voltage with the comparison voltage coming from the comparison voltage generator.

10. The electronic circuit according to claim 5, wherein the characteristic time instant is compared with the reference time instant via a flip-flop or via a comparator with a clock reference.

11. The electronic circuit according to claim 5, wherein each element is a resistor or a capacitor, and wherein the reference time instant is obtained via a set of the same second elements connected together and a set of the second switches, the second elements being the same as those of the conversion module assembly, each second element being associated with the output of a respective logic unit, each second switch being connected to the output of a respective logic unit and configured to activate, or respectively inhibit, the corresponding second element according to the high or low value at the output of the respective logic unit, and each second switch being controlled inversely relative to the switch of the conversion module which is connected to the output of the same respective logic unit.

12. The electronic circuit according to claim 11, wherein each second element is a resistor or a capacitor.

13. The electronic circuit according to claim 1, wherein each logic unit performs an inverter-type logic function during the calculation operation.

14. The electronic circuit according to claim 1, wherein the logic operation performed by the logic unit is an inversion, and the operation is a neural calculation operation, such as the MAC operation.

15. The electronic circuit according to claim 1, wherein the electronic circuit is a neuromorphic circuit able to implement a neural network with binary output, each memory cell being associated with a respective synaptic weight of a neuron, and each pair of complementary bit lines being able to receive complementary input voltages during a neural calculation operation.

16. The electronic circuit according to claim 1, comprising a first controller allowing to select the memory cells of a row which are connected to a same word line, and comprising a second controller connected to the pairs of bit lines and allowing different voltages to be applied to each pair of bit lines which are symmetrical relative to a midpoint voltage, the voltage applied to a single bit line being greater or less than that applied to the associated complementary bit line.

17. The electronic circuit according to claim 1, wherein the electronic circuit comprises a plurality of distinct sets of memory cells able to operate in parallel with a same set of pairs of complementary bit lines and distinct sets of word lines, each set of memory cells being connected to a respective set of word lines.

18. The electronic circuit according to claim 1, wherein the electronic circuit comprises a plurality of distinct sets of memory cells able to operate in parallel with a same set of word lines and distinct sets of pairs of complementary bit lines, each set of memory cells being connected to a respective set of pairs of complementary bit lines.

19. The electronic circuit according to claim 18, wherein the reading devices of two successive sets of memory cells are connected to each other via a switch.

20. The electronic circuit according to claim 19, wherein the switch is further controlled to the closed position during a neural calculation operation to perform said operation with the set of complementary input voltages received by the two sets of memory cell.
